(19) United States
(12) Patent Application Publication
(10) Pub. No.: US 2025/0204036 A1
(43) Pub. Date: Jun. 19, 2025

(54) NITRIDE-BASED PASSIVATION LAYER AT SIGE SURFACE IN NANO-FET

(71) Applicant: Taiwan Semiconductor Manufacturing Co.,Ltd., Hsinchu (TW)

(72) Inventors: Cheng-Wei Liu, Hsinchu (TW); Ji-Yin Tsai, Zhudong Township (TW); Ming-Hua Yu, Hsinchu (TW)

(21) Appl. No.: 18/662,657

(22) Filed: May 13, 2024

Related U.S. Application Data
(60) Provisional application No. 63/610,457, filed on Dec. 15, 2023.

(51) Int. Cl. H01L 27/092; H01L 21/8238; H01L 29/06; H01L 29/161; H01L 29/417; H01L 29/423; H01L 29/66; H01L 29/775; H01L 29/786

(52) U.S. Cl. CPC H10D 84/856; H10D 30/014; H10D 62/116; H10D 84/0167; H10D 84/038; H10D 30/43; H10D 30/6735; H10D 30/6757; H10D 62/121; H10D 62/832; H10D 64/258

(57) ABSTRACT

In a method of producing a nano-FET, source and drain first trenches are formed in a fin that includes a plurality of first nanostructures and a plurality of second nanostructures that are alternately formed over each other. A first semiconductor layer is disposed at bottom portions of source and drain first trenches and extends to a bottom-most nanostructure. Sidewall passivation layers are formed over sidewalls of the plurality of first nanostructures in the source and drain first trenches and inner spacers are formed on sidewalls of the plurality of second nanostructures. A second semiconductor layer is deposited in the source and drain first trenches over the first semiconductor layer to cover the sidewall passivation layers of a first nanostructure.

### PRIORITY CLAIM AND CROSS-REFERENCE

This application claims the benefit of U.S. Provisional Application No. 63/610,457, filed on Dec. 15, 2023, entitled “NITRIDE-BASED SI (GE) SURFACE DECORATION LAYER TO ACHIEVE THE HYBRID SHEET STRUCTURE IN GAAFET,” which is incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments of the disclosure.

FIGS. 2, 3, 4, and 5 are cross-sectional A-A′ views, illustrated in FIG. 1, of intermediate stages in the manufacturing of nano-FETs, in accordance with some embodiments of the disclosure.

FIGS. 6A and 6B are cross-sectional B-B′ views, illustrated in FIG. 1, of intermediate stages in the manufacturing of nano-FETs, in accordance with some embodiments of the disclosure.

FIGS. 7A, 7B, 8A, 8B, 9A, 9B, 10A, 10B, 11A, 11B, 11C, 12A, 12B, 12C, 12D, 12E, 12F, 12G, 13A, 13B, 13C, 14A, 14B, 15A, 15B, 16A, 16B, 17A, 17B, 18A, 18B, 18C, 19A, 19B, 19C, 20A, 20B, and 20C are cross-sectional views of intermediate stages in the manufacturing of nano-FETs, in accordance with some embodiments of the disclosure.

FIGS. 21A, 21B, and 21C are cross-sectional views of a nano-FET, in accordance with some embodiments of the disclosure.

FIGS. 22A and 22B are cross-sectional views of a nano-FET, in accordance with some embodiments of the disclosure.

FIGS. 23A, 23B, and 23C illustrate cross-sectional views of an intermediate stage in the manufacturing of source/drain regions of two or more nano-FETs on a substrate, in accordance with some embodiments of the disclosure.

FIGS. 24A, 24B, 25A, 25B, 26A, 26B, 27A, and 27B illustrate cross-sectional views of passivation layers in the source/drain regions of nano-FETs, in accordance with some embodiments of the disclosure.

FIG. 28 illustrates a flow diagram of a process for manufacturing of nano-FETs, according to some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, in a nano-FET, a passivation layer produced between the source/drain region and one or more channels (e.g., nanosheets) may reduce source-drain current of the nano-FET. At different locations of the substrate, different nano-FETs may be created with different number of passivation layers produced between the source/drain region and the channels. Thus, the nano-FETs source-drain currents may be different at different locations of the substrate.

Also, when in the process of producing the source/drain regions, deposition and/or etching is used, the source/drain region elements may move into the channel region during deposition or the etching may change the channel region size and, thus, may affect the critical dimensions. Therefore, a passivation layer may be used between the source/drain regions and the channel region to prevent the migration of the elements between the source/drain regions and/or prevent the modification of the critical dimension.

Embodiments are described in a particular context, a die including nano-FETs. Various embodiments may be applied, however, to dies including other types of transistors (e.g., fin field-effect transistors (finFETs), planar transistors, or the like) in lieu of or in combination with the nano-FETs.

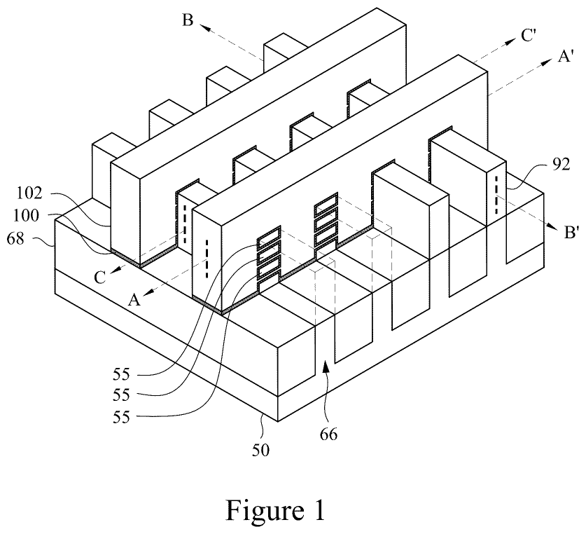

FIG. 1 illustrates an example of nanostructure field-effect transistors (nano-FETs) in a three-dimensional view, in accordance with some embodiments of the disclosure. FIG. 1 shows an example nano-FETs (e.g., nanowire FETs, nanosheet FETs (Nano-FETs), or the like) in a three-dimensional view, where some features of the nano-FETs are omitted for illustration clarity. The nano-FETs may be nanosheet field-effect transistors (NSFETs), nanowire field-effect transistors (NWFETs), gate-all-around field-effect transistors (GAAFETs), or the like.

The nano-FETs include nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may include a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 (e.g., electrodes) are over the gate dielectric layers 100 to produce a gate structure. Epitaxial source/drain regions 92 are disposed on the fins 66 on opposing sides of the gate dielectric layers 100 and the gate electrodes 102. Epitaxial source/drain regions 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

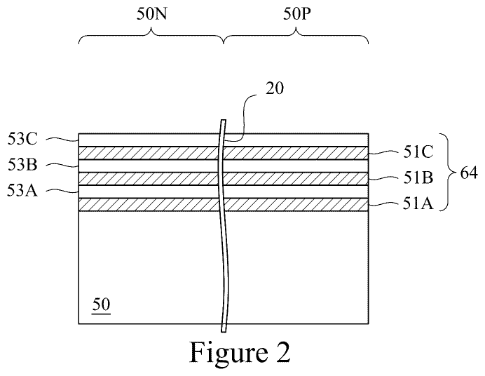

FIGS. 2, 3, 4, and 5 are cross-sectional A-A′ views, illustrated in FIG. 1, of intermediate stages in the manufacturing of nano-FETs, in accordance with some embodiments of the disclosure. In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 may be formed over the substrate 50. The multi-layer stack 64 includes alternating layers of first semiconductor layers 51A, 51B, and 51C (collectively referred to as first semiconductor layers 51) and second semiconductor layers 53A, 53B, and 53C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

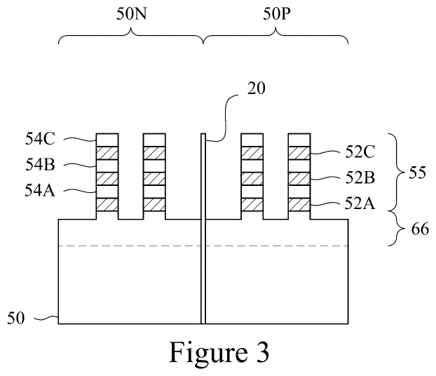

As shown in FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A, 52B, and 52C (collectively referred to as the first nanostructures 52) from the first semiconductor layers 51 and define second nanostructures 54A, 54B, and 54C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

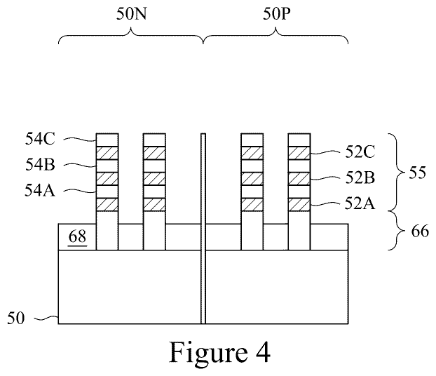

In FIG. 4, shallow trench isolation (STI) regions 68 may be formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may include the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

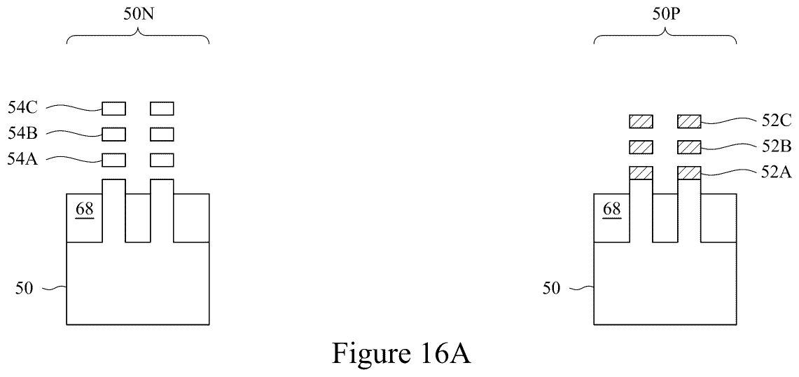

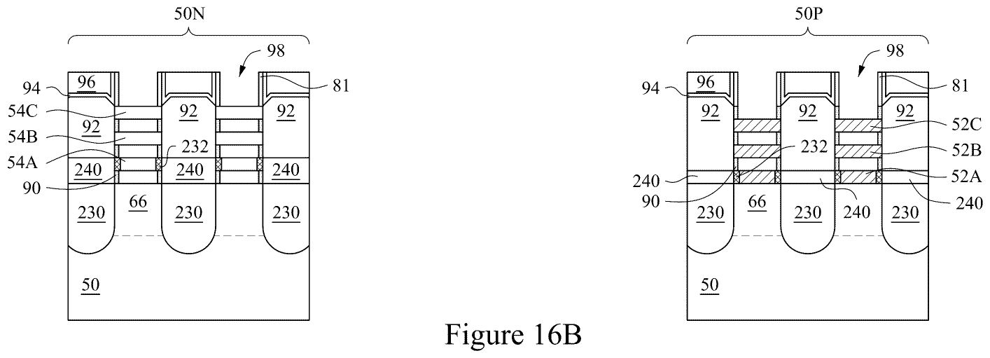

After the implants in the n-type region 50N and the p-type region 50P, an anneal process may be performed to repair implant damage and to activate the p-type and/or n-type impurities that were implanted. In some embodiments, the grown materials of epitaxial fins may be in situ doped during growth, which may obviate the implantations, although in situ and implantation doping may be used together. In some embodiments, initially, a dummy gate structure is produced over channel regions to protect the channel regions from being etched. Removal of the dummy gate structure and producing a gate structure is discussed below with respect to FIGS. 16A, 16B, 17A, 17B, 18A and 18C. To produce the dummy gate structure, a dummy dielectric layer is patterned by a mask layer. Then, keeping the dialectic and possibly the layer over the channel regions and etching the mask layer and the dielectric layer from other regions.

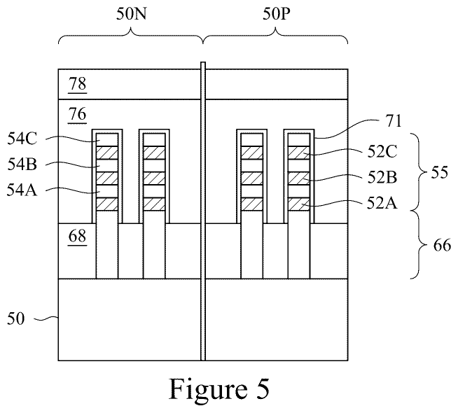

In FIG. 5, using acceptable photolithography techniques, a mask layer 78 is patterned. The pattern of the mask layer 78 then may be transferred to the dummy gate layer 76 and to a dummy dielectric layer 71 to form dummy gates and dummy gate dielectrics, respectively. The dummy gates cover respective channel regions of the fins 66. The patterned mask layer 78 may be used to physically separate each of the dummy gates from adjacent dummy gates. The dummy gates may also have a lengthwise direction substantially perpendicular to the lengthwise direction of respective fins 66.

The dummy dielectric layer 71 may be formed on the fins 66 and/or the nanostructures 55. The dummy dielectric layer 71 may be, for example, silicon oxide, silicon nitride, a combination thereof, or the like, and may be deposited or thermally grown according to acceptable techniques. A dummy gate layer 76 is formed over the dummy dielectric layer 71, and the mask layer 78 is formed over the dummy gate layer 76. The dummy gate layer 76 may be deposited over the dummy dielectric layer 71 and then planarized, such as by a CMP. The mask layer 78 may be deposited over the dummy gate layer 76. The dummy gate layer 76 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 76 may be deposited by physical vapor deposition (PVD), CVD, sputter deposition, or other techniques for depositing the selected material. The dummy gate layer 76 may be made of other materials that have a high etching selectivity from the etching of isolation regions. The mask layer 78 may include, for example, silicon nitride, silicon oxynitride, or the like. In this example, a single dummy gate layer 76 and a single mask layer 78 are formed across the n-type region 50N and the p-type region 50P. It is noted that the dummy dielectric layer 71 is shown covering only the fins 66 and the nanostructures 55 for illustrative purposes only. In some embodiments, the dummy dielectric layer 71 may be deposited such that the dummy dielectric layer 71 covers the STI regions 68, such that the dummy dielectric layer 71 extends between the dummy gate layer 76 and the STI regions 68.

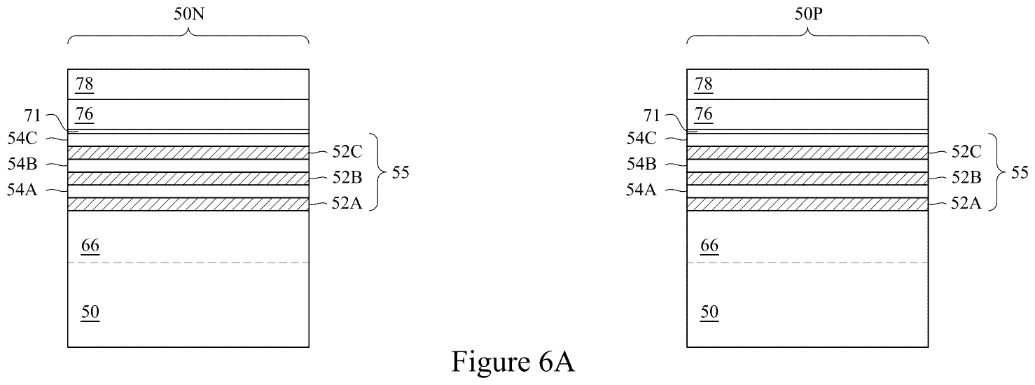

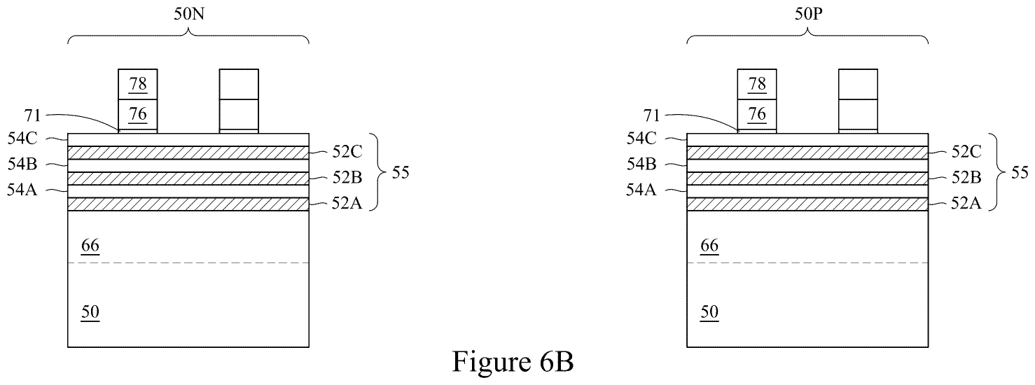

FIGS. 6A and 6B are cross-sectional B-B′ views, illustrated in FIG. 1, of intermediate stages in the manufacturing of nano-FETs, in accordance with some embodiments of the disclosure. As shown, in FIG. 6A and as described with respect to FIG. 5, the dummy dielectric layer 71, the dummy gate layer 76, and the mask layer 78 are formed over the nanostructures 55 of the fins 66. As shown in FIG. 6B, after the photolithography and the dummy dielectric layer 71, the dummy gate layer 76, and the mask layer 78 only remains over channel regions and are removed from other regions in both the n-type region 50N and the p-type region 50P.

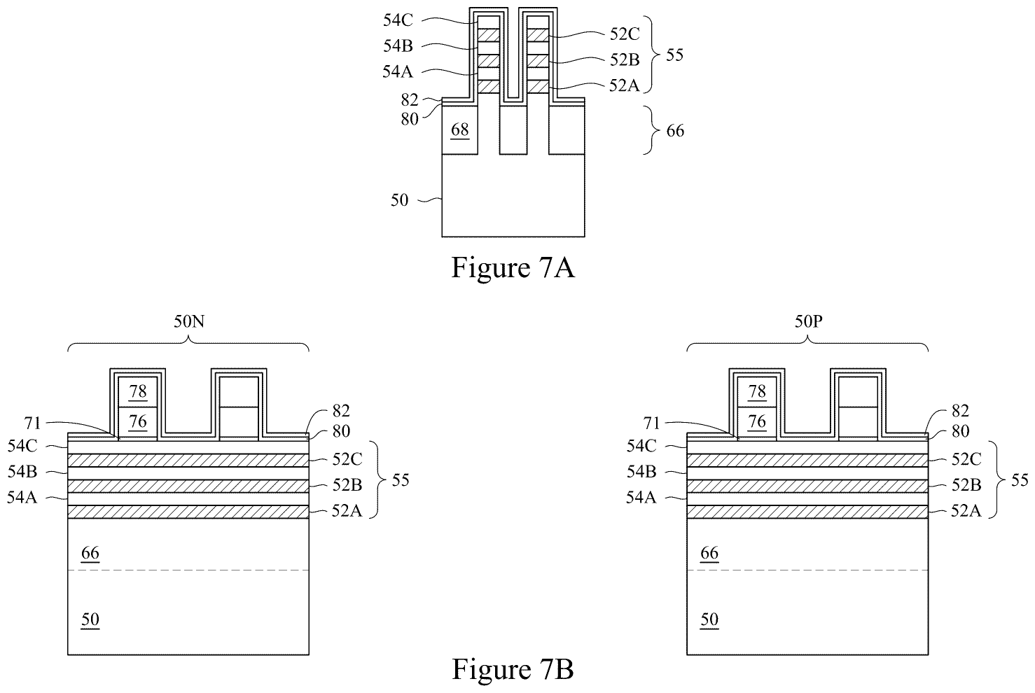

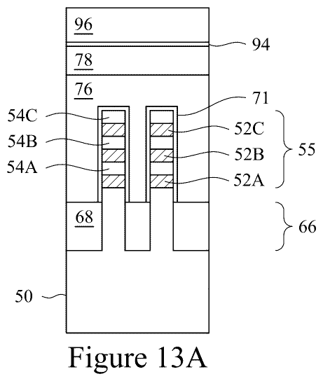

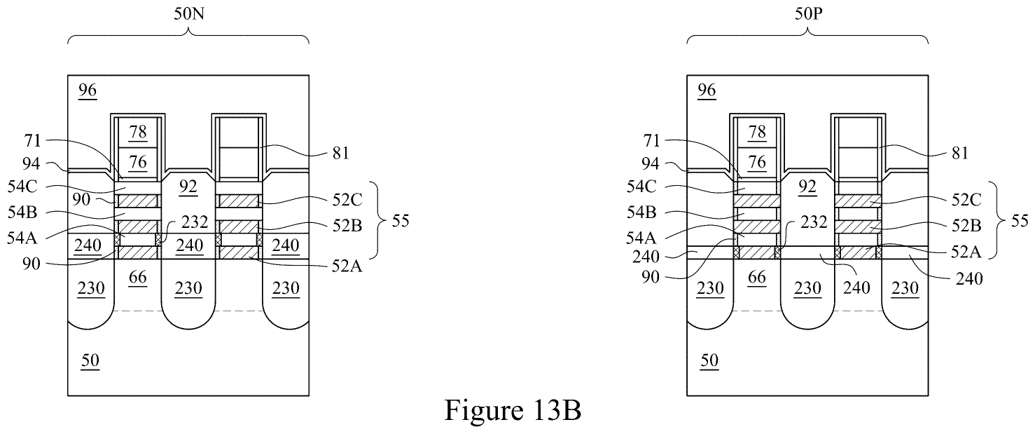

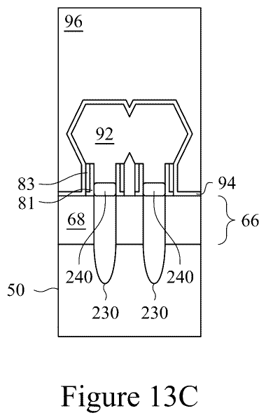

FIGS. 7A, 7B, 8A, 8B, 9A, 9B, 10A, 10B, 11A, 11B, 11C, 12A, 12B, 12C, 12D, 12E, 12F, 12G, 13A, 13B, 13C, 14A, 14B, 15A, 15B, 16A, 16B, 17A, 17B, 18A, 18B, 18C, 19A, 19B, 19C, 20A, 20B, and 20C are cross-sectional views of intermediate stages in the manufacturing of nano-FETs, in accordance with some embodiments of the disclosure. FIGS. 13A, 14A, 15A, 16A, 17A, 18A, 19A, and 20A illustrate reference cross-section A-A′ illustrated in FIG. 1. FIGS. 7B, 8B, 9B, 10B, 11B, 11C, 12A, 12B, 12C, 12D, 12E, 13B, 14B, 15B, 16B, 17B, 18B, 19B, and 20B illustrate reference cross-section B-B′ illustrated in FIG. 1. FIGS. 7A, 8A, 9A, 10A, 11A, 12A, 12C, 12F, 12G, 13C, 18C, 19C, and 20C, illustrate reference cross-section C-C′ illustrated in FIG. 1. FIGS. 7A, 8A, 9A, 10A, 11A, 12A, 12C, 12F, 12G, 13C, 18C, 19C, and 20C illustrate cross-sections in both of the n-type regions 50N and the p-type regions 50P.

In FIGS. 7A and 7B, a first spacer layer 80 and a second spacer layer 82 are formed over the structures illustrated in FIG. 5 and one of 6A or 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the mask layer 78; and sidewalls of the dummy gate layer 76 and the dummy dielectric layer 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An annealing may be used to repair implant damage and to activate the implanted impurities.

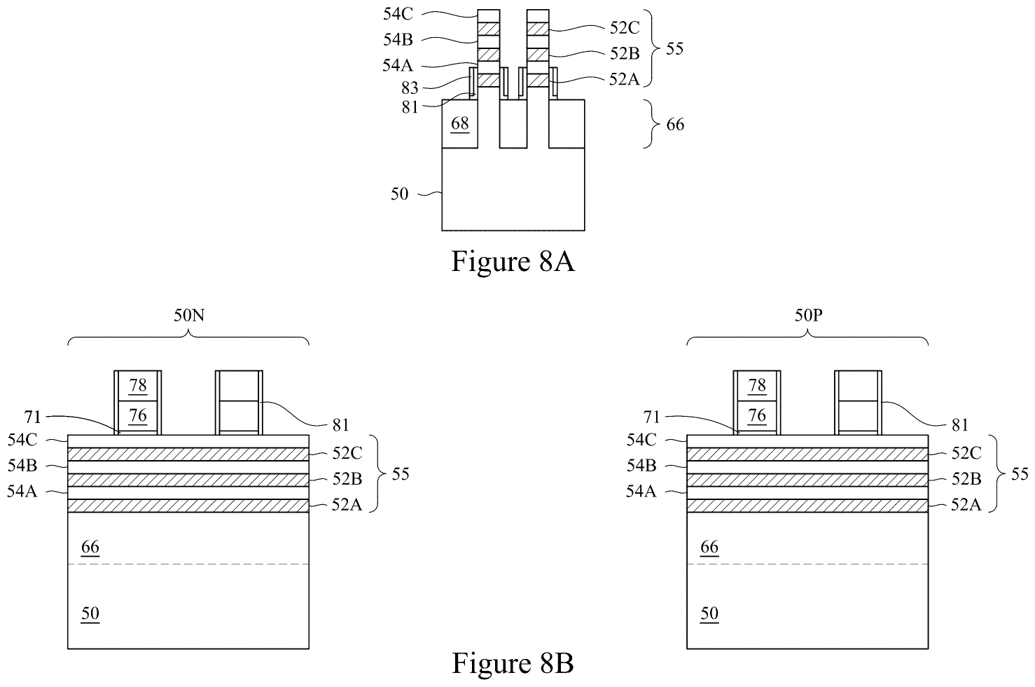

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the mask layer 78, the dummy gate layer 76, and the dummy dielectric layer 71, and the first spacers 81 are disposed on sidewalls of the mask layer 78, the dummy gate layer 76, and the dummy dielectric layers 71. In other embodiments, a portion of the second spacer layer 82 may remain over the first spacer layer 80 adjacent the mask layer 78, the dummy gate layer 76, and the dummy dielectric layer 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

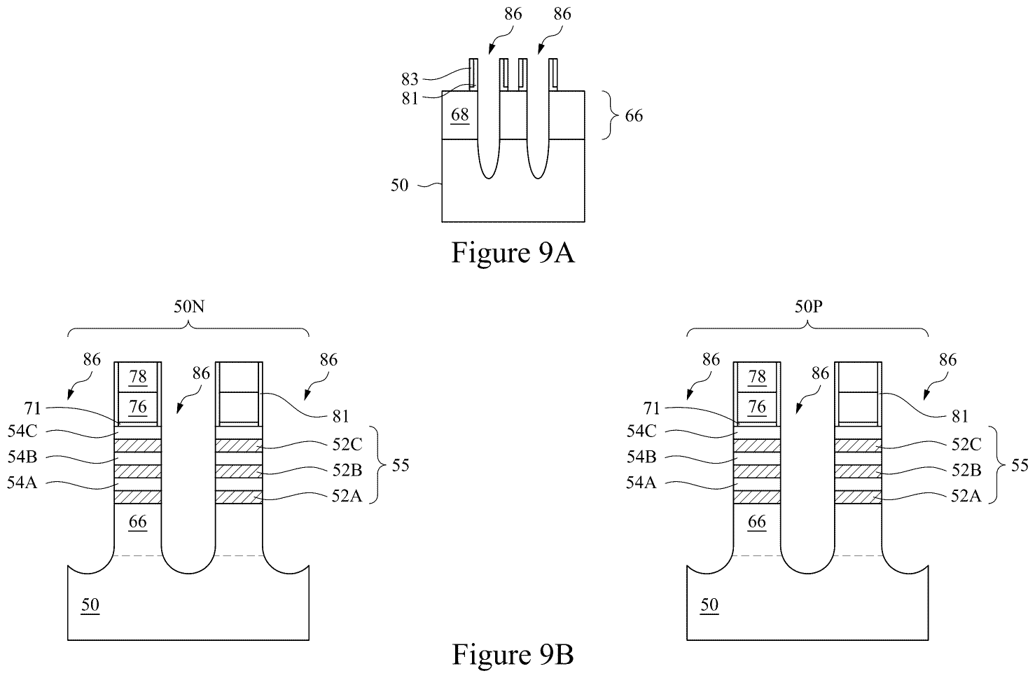

In FIGS. 9A and 9B, trenches 86 are formed in the fins 66, the nanostructures 55, and the substrate 50, in accordance with some embodiments. The trenches 86 may extend through the first nanostructures 52 and the second nanostructures 54, and into the substrate 50. As illustrated in FIG. 9A, top surfaces of the STI regions 68 may be level with bottom surfaces of the trenches 86. In various embodiments, the fins 66 may be etched such that bottom surfaces of the trenches 86 are disposed below the top surfaces of the STI regions 68; or the like. The trenches 86 may be formed by etching the fins 66, the nanostructures 55, and the substrate 50 using anisotropic etching processes, such as RIE, NBE, or the like. The first spacers 81, the second spacers 83, and the mask layer 78 mask portions of the fins 66, the nanostructures 55, and the substrate 50 during the etching processes used to form the trenches 86. A single etch process or multiple etch processes may be used to etch each layer of the nanostructures 55 and/or the fins 66. Timed etch processes may be used to stop the etching of the trenches 86 after the trenches 86 reach a desired depth.

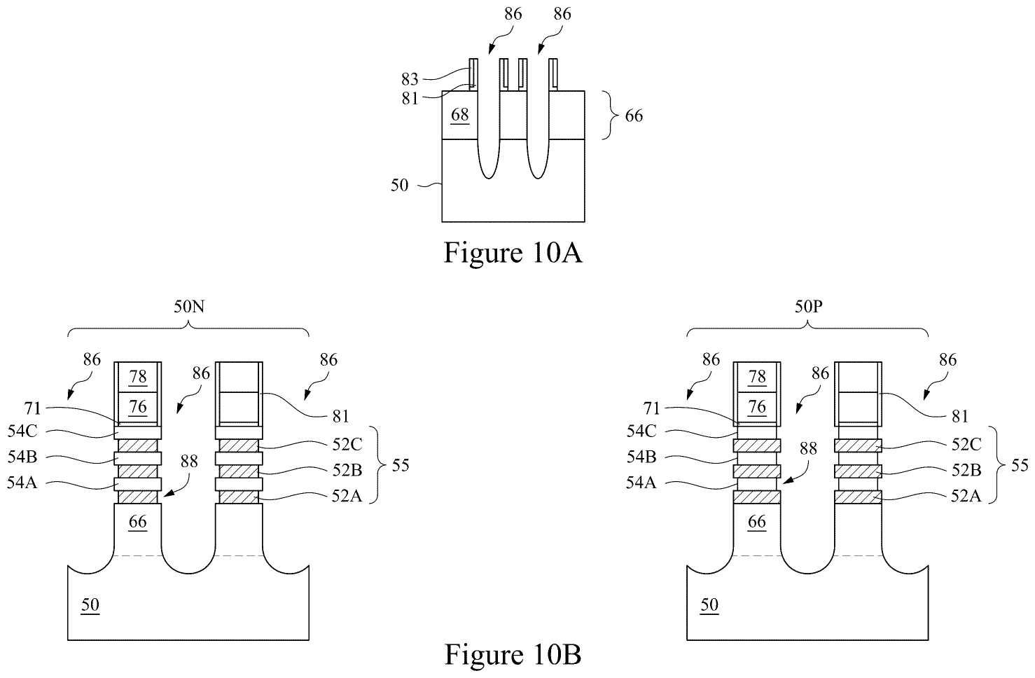

In FIGS. 10A and 10B, portions of sidewalls of the layers of the multi-layer stack 64 formed of the first semiconductor materials (e.g., the first nanostructures 52) exposed by the trenches 86 are etched to form sidewall recesses 88 in the n-type region 50N, and portions of sidewalls of the layers of the multi-layer stack 64 formed of the second semiconductor materials (e.g., the second nanostructures 54) exposed by the trenches 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

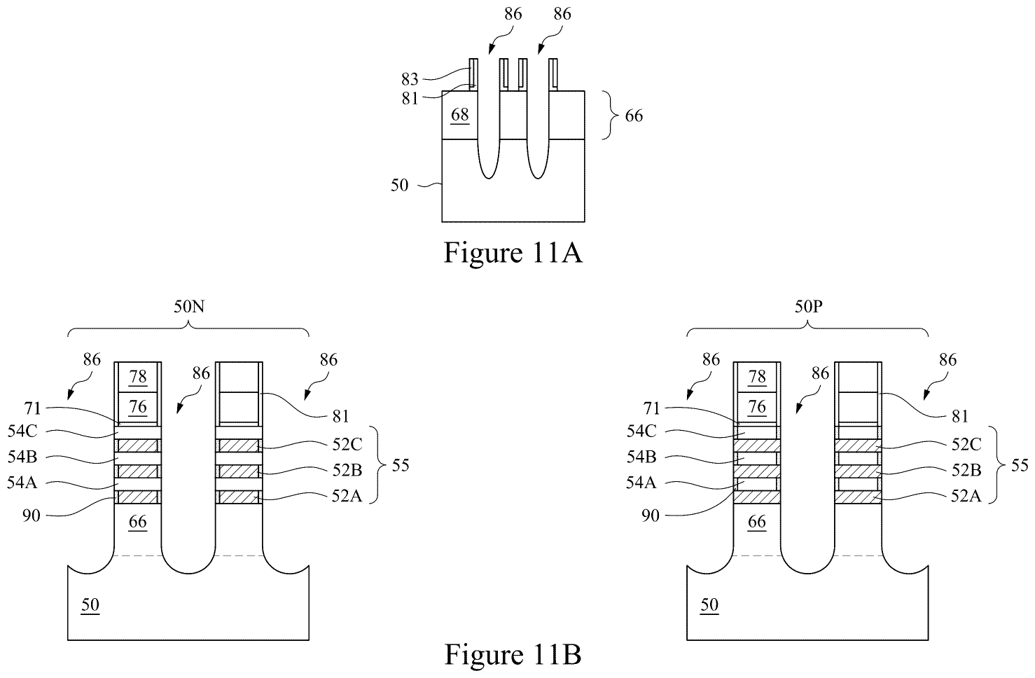

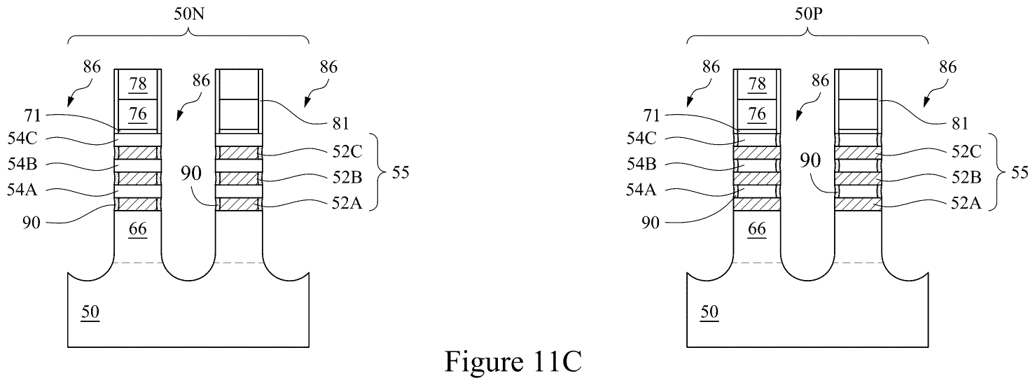

In FIGS. 11A, 11B, and 11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the trenches 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may include a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

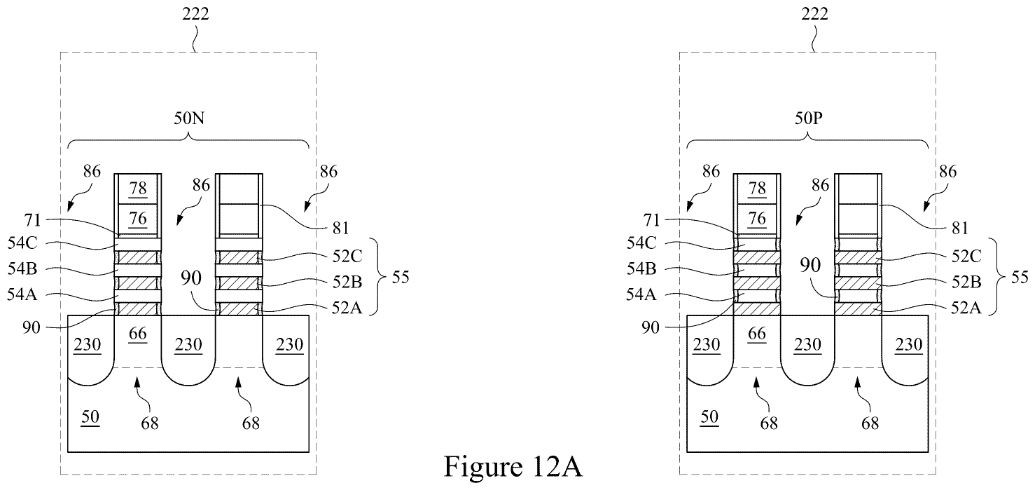

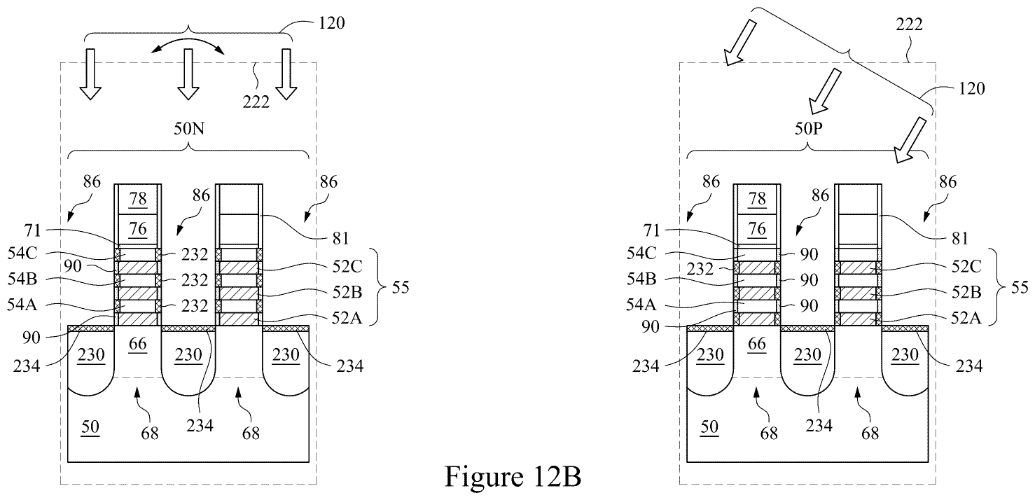

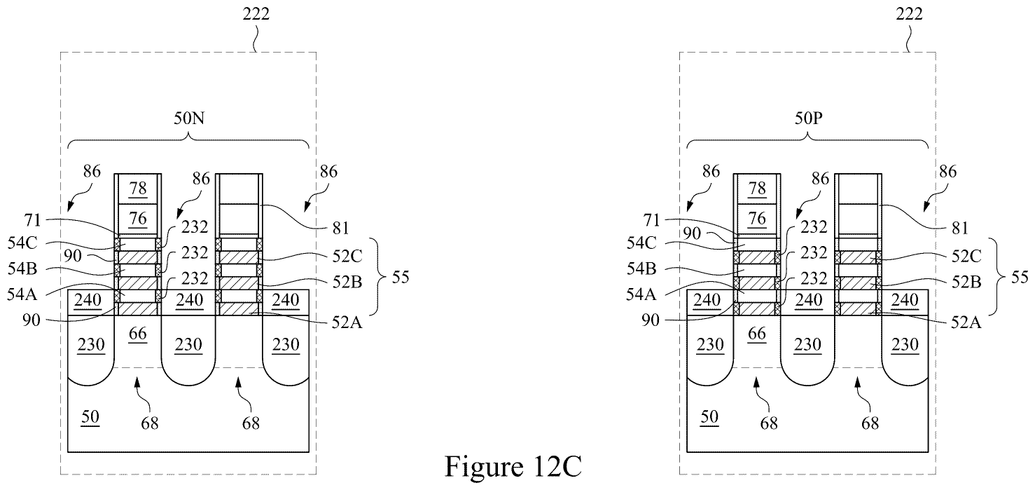

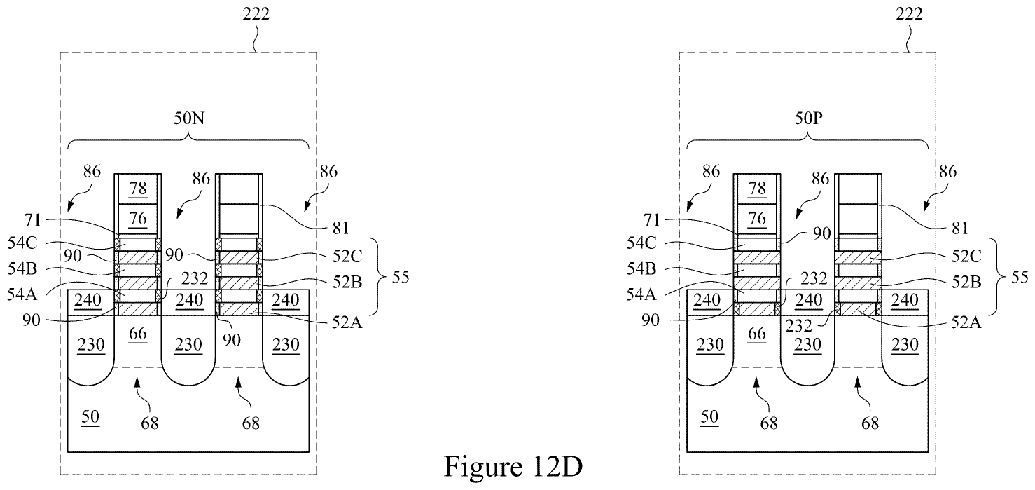

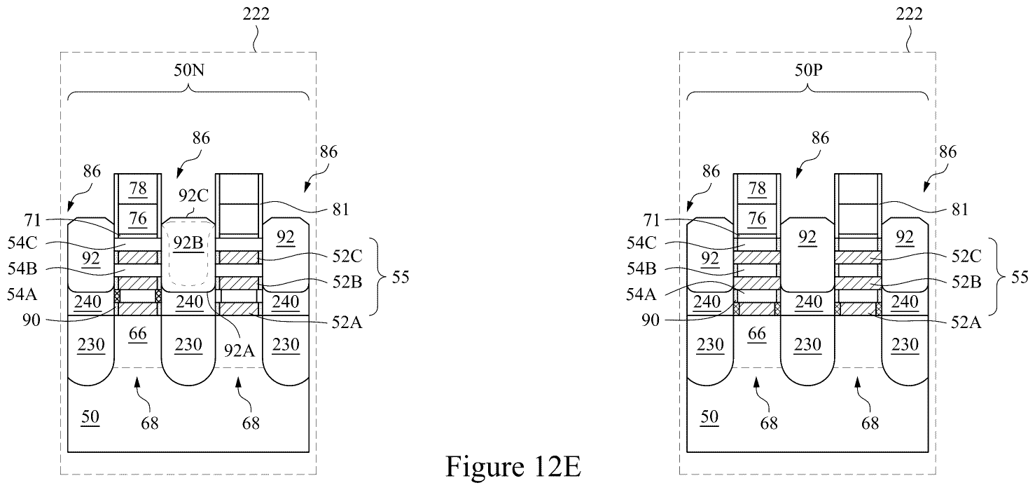

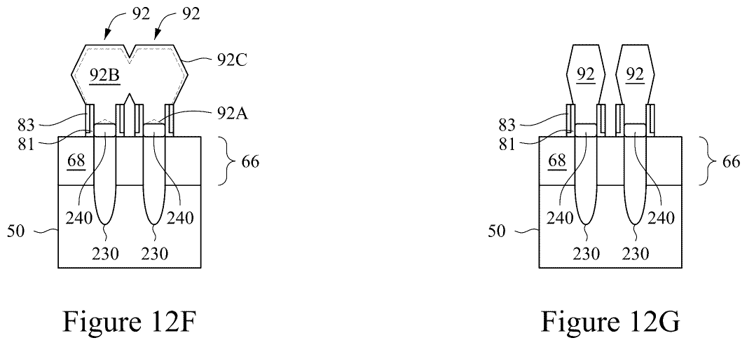

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A, 12B, 12C, 12D, and 12E) by subsequent etching processes, such as etching processes used to form gate structures.

In FIGS. 12A, 12B, 12C, 12D, and 12E, as shown, a bottom portion 230, e.g., a bottom layer, of the trenches 86 (source/drain recesses or source/drain trenches) are filled with a semiconductor material and the bottom portion 230 is filled up to the bottommost nanostructure 54 and the bottommost inner spacers 90 of the nanostructure 54. In some embodiments, the bottom portion 230 is a mesa or is part of a mesa that connects two or more semiconductor fins 66 and is filled with SiGe semiconductor material such as Si₁₋ₓGeₓ with x between 0.1 and 0.4, e.g., 0.35. In some embodiments, the SiGe semiconductor material of the bottom portion 230 includes a dopant material. In some embodiments, the bottom portion 230 is filled up to the bottommost nanostructure, e.g., the bottommost nanostructure 52 in the n-type region 50N and in the p-type region 50P. The inner spacers 90 have a concave, a convex, or a flat shape at a sidewall of the trenches 86.

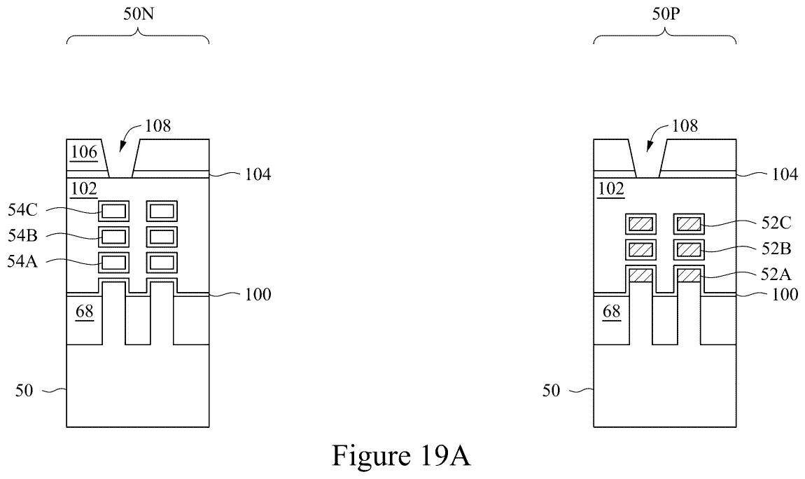

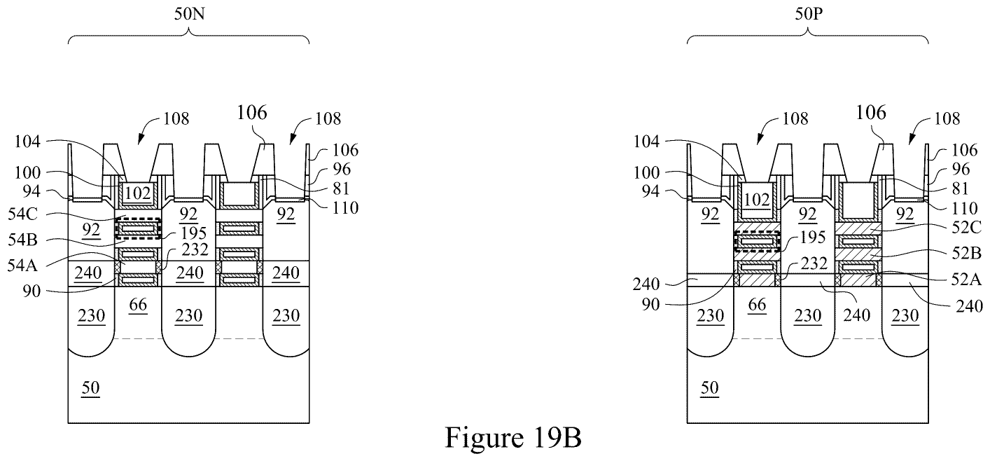

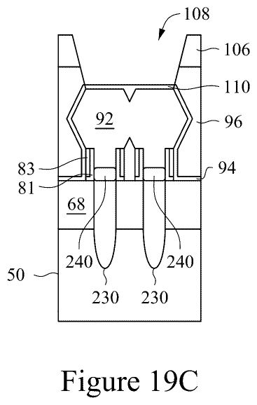

In some embodiments, in the n-type region 50N, the nanostructures 52 will subsequently be removed and replaced with gate structures that are wrapped around the nanostructures 54. In the p-type region 50P, the nanostructures 54 may subsequently be removed and replaced with gate structures that are wrapped around the nanostructures 52 (See gate structures 195 in FIG. 19B). As shown below, the nanostructures 54, which are disposed between adjacent pairs of the epitaxial source/drain regions 92 act as the channel regions (nanowires or nanosheets) or channels and the gate structures wrap around the channel regions in the n-type region 50N. The nanostructures 52 may act as the channel regions in the p-type region 50P.

In FIG. 12B, the source/drain trenches 86 are exposed to a plasma material 120, e.g., a directed plasma material or a plasma beam, such that a passivation layer 232, e.g., a sidewall passivation layer, is created over the nanostructures 54 of n-type region 50N and over the nanostructure 52 of the p-type region 50P. Another layer 234, a passivation layer, is created over the bottom portion 230. The passivation layer 232 may prevent the etching of the nanostructures 54 or 52 and may prevent the migration of the bottom portion 230 material into the nanostructures 54 or 52 and, thus, may preserve a critical dimension (CD) of the nano-FET. In some embodiments, the plasma material 120 includes one of silicon, carbon, oxygen, nitrogen, or a combination thereof and may produce passivation layers 232 such as silicon nitride, silicon dioxide, silicon carbide, amorphous silicon, poly silicon, or crystalized silicon. In some embodiments, the passivation layer 232 prevents the nanostructures 54 to act as channel regions and, thus, reduces the current of the nano-FET. In some embodiments as shown in FIG. 12B, the plasma material 120 may be directional and the direction may be changed from downward, to right-tilted, or to left-tilted such that the plasma material impinges on the sidewalls of the nanostructures or on top of the bottom portion 230. In some embodiments, the passivation layer 232 over the nanostructures 54 of n-type region 50N or over the nanostructure 52 of the p-type region 50P is produced by atomic layer deposition of silicon, carbon, oxygen, nitrogen, or a combination thereof followed by a thermal annealing of at least 900 degrees centigrade. Also, the layer 234 over the bottom portion 230 may be produced as described above by atomic layer deposition followed by thermal annealing. In some embodiments, the plasma is nitrogen and the nitrogen diffuses into the nanostructures 54 and with the silicon of the nanostructures 54 creates the passivation layer 232 that is a crystalline SiN barrier to prevent the diffusion of the Ge into the nanostructures 54. Also, the SiN barrier may prevent etching of the nanostructures 54 and may preserve the critical dimension. In some embodiments that the plasma is nitrogen and the nitrogen diffuses into the nanostructures 54, polycrystalline SiN and/or amorphous SiN is produced in the passivation layer 232.

As shown in FIG. 12C, the layer 234 is removed from over the bottom portion 230 material and then another semiconductor layer 240 is deposited over the bottom portion 230. By removing the layer 234, bottom portion 230 and the semiconductor layer 240 become electrically connected to each other. The semiconductor layer 240 may cover one or more, e.g., one or two, of the nanostructures 54 of the n-type region 50N, or the nanostructures 52 of the p-type region 50P. The semiconductor layer 240 also covers the passivation layer 232. The nanostructures 54 or 52 with the passivation layer 232 that are covered by the semiconductor layer 240 may not contribute to the current of the nano-FET and, thus, reduces the current of the nano-FET. Therefore, depending on how much current is required for the nano-FET, one or more of the nanostructures 54 or 52 with the passivation layer 232 may be covered by the semiconductor layer 240. In some embodiments, no nanostructures 54 or 52 may have the passivation layer 232 or no nanostructures 54 or 52 may be covered by the semiconductor layer 240. The passivation layer may be formed at a temperature between 300 degrees centigrade and 700 degrees centigrade. In some embodiments, the semiconductor layer 240 includes the SiGe semiconductor material such as Si₁₋ₓGeₓ with x between 0.1 and 0.3, e.g., 0.25. In some embodiments, the SiGe semiconductor material of the semiconductor layer 240 includes a dopant material. In some embodiments, after removal of the layer 234, residue elements, e.g., nitrogen residue, remains on top part of the bottom portion 230. The bottom portion 230, the semiconductor layer 240, and the epitaxial source/drain regions 92 may have an n-type (e.g., arsenic or phosphorus) dopant concentration or a p-type (e.g., boron) dopant concentration. In some embodiments, the dopant concentration of the epitaxial source/drain regions 92 is between about 10¹⁹ cm⁻³ and about 10²¹ cm⁻³ and the dopant concentration of the bottom portion 230 and the semiconductor layer 240 is between about 10¹⁴ cm⁻³ and about 10¹⁶ cm⁻³.

As shown in FIG. 12D, the passivation layers 232 that are not covered by the semiconductor layer 240 are removed by an etching process such as a wet or dry etch process, e.g., an anisotropic or directed dry etching. As shown in FIG. 12E, after removal of the passivation layers 232 that are not covered by the semiconductor layer 240, an epitaxial source/drain regions 92 is grown over the semiconductor layer 240 in the source/drain trenches 86. The epitaxial source/drain regions 92 covers the remaining nanostructures 54 or 52 that do not have the passivation layers 232 and becomes in electrical contact with the nanostructures 54 or 52. In some embodiments, the semiconductor fin 66 includes up to 10 nanostructures 54 or 52. Out of the 10 nanostructures 54 or 52, none, one, two, or up to 9 of the nanostructures 54 or 52 may have the passivation layers 232 (closed channels) and may be covered by the semiconductor layer 240 and, thus, may not contribute to the current of the nano-FET. The remaining nanostructures 54 or 52 may not have the passivation layers 232 (open channels) and be in contact with the epitaxial source/drain regions 92 and may contribute to the nano-FET current. Depending on how much current may be required in a location of a semiconductor/integrated circuit, the number of open channels vs. closed channels of the nano-FET may be determined. In some embodiments, the epitaxial source/drain regions 92 includes the SiGe semiconductor material such as Si₁₋ₓGeₓ with x between 0.1 and 0.3, e.g., 0.2, and may include a dopant material.

As shown in FIG. 12E, epitaxial source/drain regions 92 are formed in the trenches 86. In some embodiments, the epitaxial source/drain regions 92 may exert stress on the second nanostructures 54 in the n-type region 50N and on the first nanostructures 52 in the p-type region 50P, thereby improving performance. As illustrated in FIG. 12E, the epitaxial source/drain regions 92 are formed in the trenches 86 such that each dummy gate layer 76 is disposed between respective neighboring pairs of the epitaxial source/drain regions 92. In some embodiments, the first spacers 81 are used to separate the epitaxial source/drain regions 92 from the dummy gate layer 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the trenches 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the trenches 86 in the p-type region 50P. The epitaxial source/drain regions 92 may include any acceptable material appropriate for p-type nano-FETs. For example, if the first nanostructures 52 are silicon germanium, the epitaxial source/drain regions 92 may include materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same two or more nano-FET to merge as illustrated by FIG. 12F. In other embodiments, adjacent epitaxial source/drain regions 92 remain separated after the epitaxy process is completed as illustrated by FIG. 12G. In the embodiments, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68 as shown in FIGS. 12F and 12G, which are at cross-section C-C′ and also show the bottom portion 230 and the semiconductor layer 240 in the trenches 86.

The epitaxial source/drain regions 92 may include one or more semiconductor material layers. For example, the epitaxial source/drain regions 92 may include a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 include three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

In FIGS. 13A, 13B, and 13C, a first interlayer dielectric (ILD) 96 is deposited over the structure illustrated in FIG. 5. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the mask layer 78, and the first spacers 81. The CESL 94 may include a dielectric material, such as, silicon nitride, silicon oxide, silicon oxynitride, or the like, having a different etch rate than the material of the overlying first ILD 96.

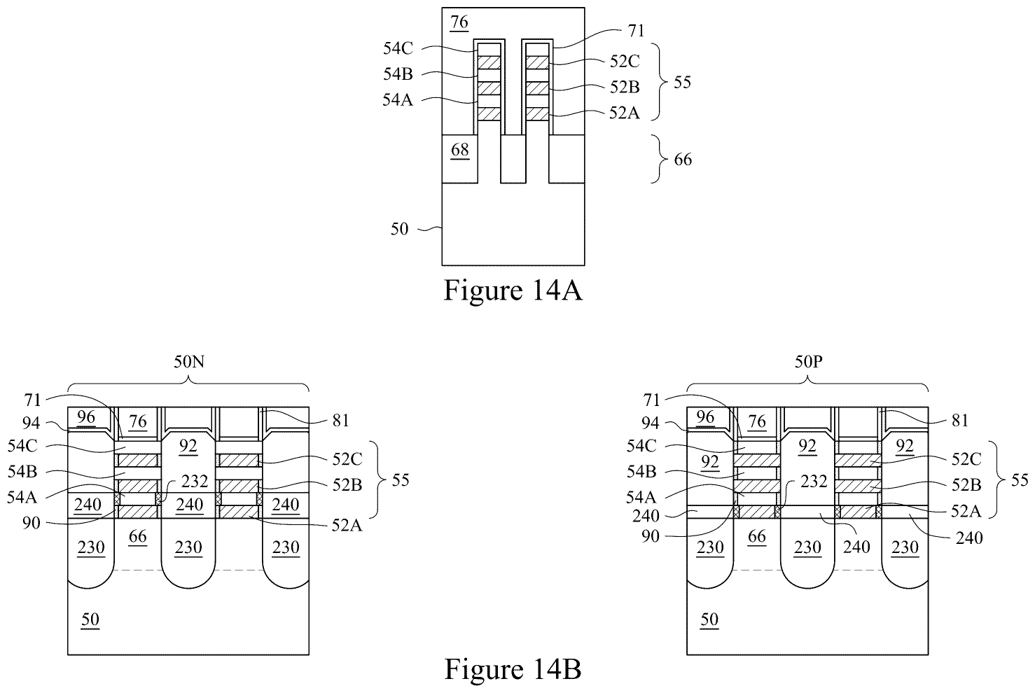

In FIGS. 14A, 14B, and 14C, a planarization process, such as a CMP, may be performed to level the top surface of the first ILD 96 with the top surfaces of the dummy gate layer 76 or the mask layer 78. The planarization process may also remove the mask layer 78 on the dummy gate layer 76, and portions of the first spacers 81 along sidewalls of the mask layer 78. After the planarization process, top surfaces of the dummy gate layer 76, the first spacers 81, and the first ILD 96 are level within process variations. Accordingly, the top surfaces of the dummy gate layer 76 are exposed through the first ILD 96. In some embodiments, the mask layer 78 may remain, in which case the planarization process levels the top surface of the first ILD 96 with top surface of the mask layer 78 and the first spacers 81.

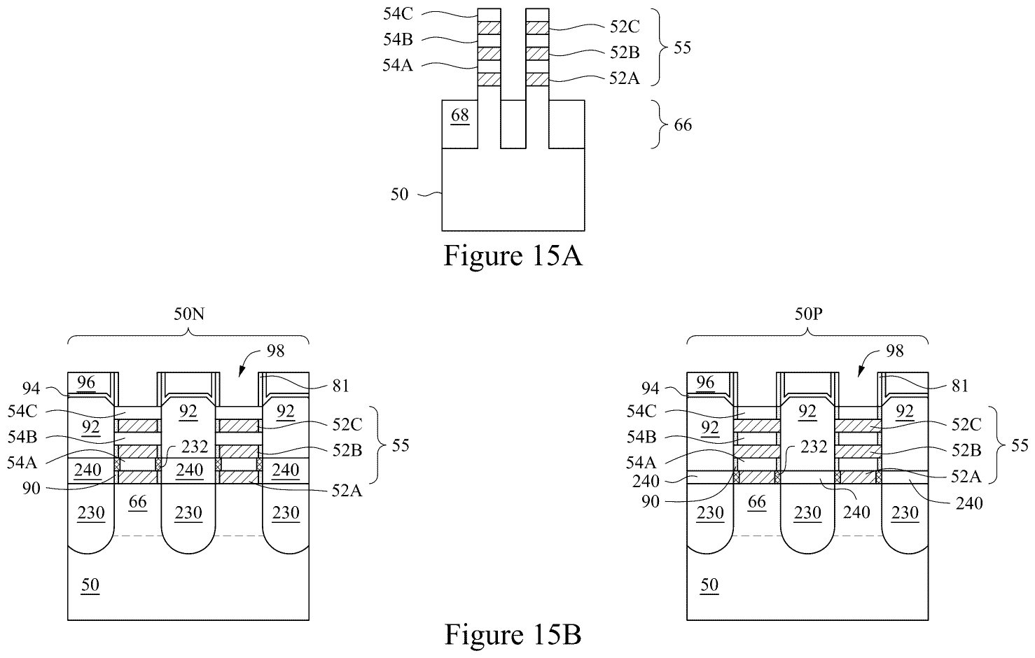

In FIGS. 15A and 15B, the dummy gate layer 76, and the mask layer 78 if present, are removed in one or more etching steps, so that recesses 98 are formed. Portions of the dummy dielectric layers 71 in the recesses 98 are also be removed. In some embodiments, the dummy gate layer 76 and the dummy dielectric layers 71 are removed by an anisotropic dry etch process. For example, the etching process may include a dry etch process using reaction gas(es) that selectively etch the dummy gate layer 76 at a faster rate than the first ILD 96 or the first spacers 81. Each recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 71 may be used as etch stop layers when the dummy gate layer 76 are etched. The dummy dielectric layers 71 may then be removed after the removal of the dummy gate layer 76.

In FIGS. 16A and 16B, the first nanostructures 52 in the n-type region 50N and the second nanostructures 54 in the p-type region 50P are removed extending the recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A, 54B, and 54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

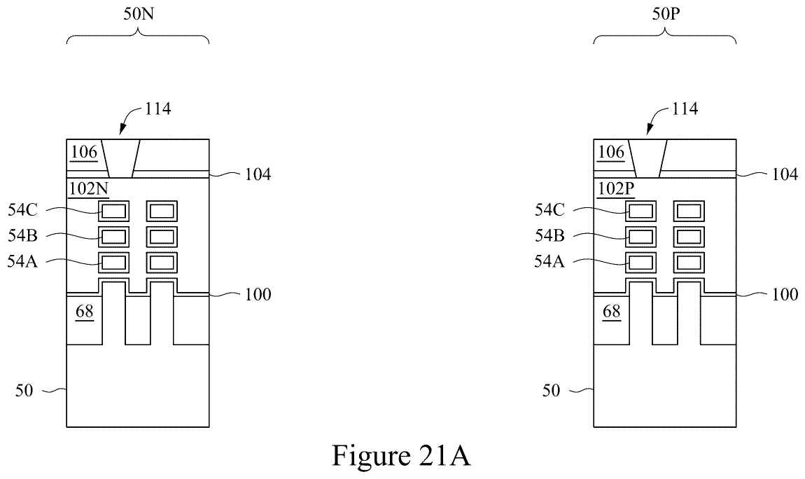

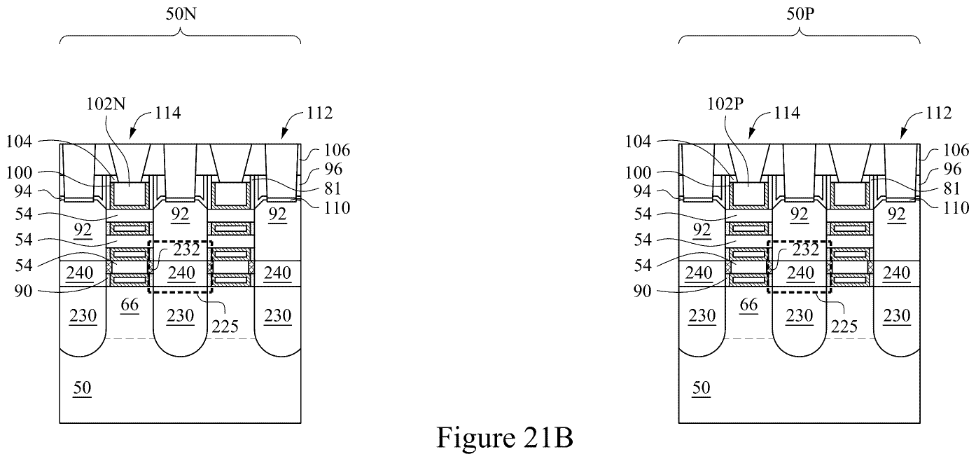

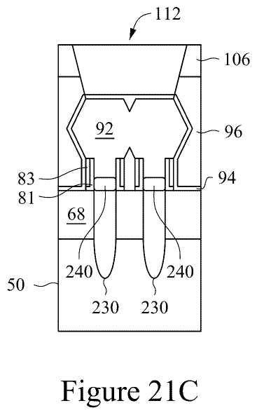

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 21A, 21B, and 21C illustrate a structure resulting from such embodiments where the channel regions in both the p-type region 50P and the n-type region 50N are provided by the second nanostructures 54 and include silicon, for example.

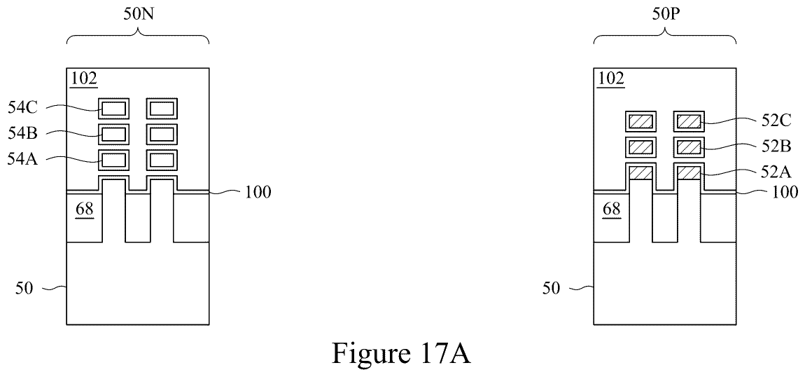

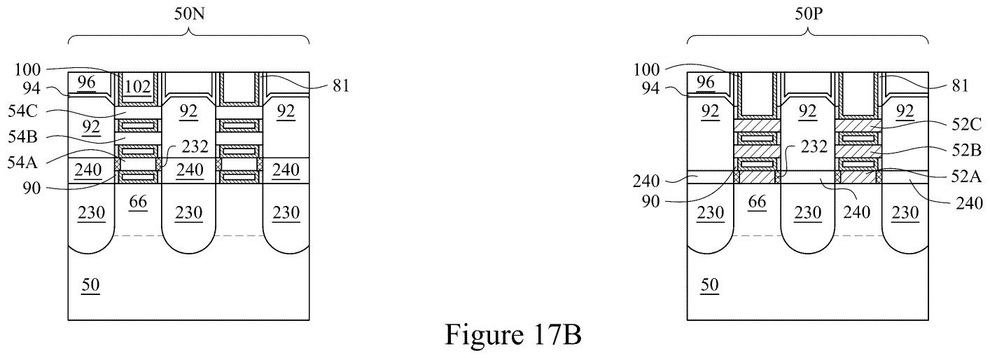

FIGS. 17A and 17B show gate dielectric layers 100 and gate electrodes 102 that may be formed for replacement gates. The gate dielectric layers 100 are deposited conformally in the recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 68.

In accordance with some embodiments, the gate dielectric layers 100 include one or more dielectric layers, such as an oxide, a metal oxide, the like, or combinations thereof. For example, in some embodiments, the gate dielectrics may include a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may include any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.” In some embodiments, the nanostructures 54 in the n-type region 50N are configured, e.g., formed or designed, to perform as channels of the nano-FET and the nanostructures 52 in the p-type region 50P are configured, e.g., formed or designed, to perform as channels of the nano-FET. Also, the nanostructures 52 in the n-type region 50N include the gate electrodes 102, are electrically connected to each other, and are formed or designed to perform as part of the gate structure. The nanostructures 54 in the p-type region 50P include the gate electrodes 102, are electrically connected to each other, and are formed or designed to perform as part of the gate structure.

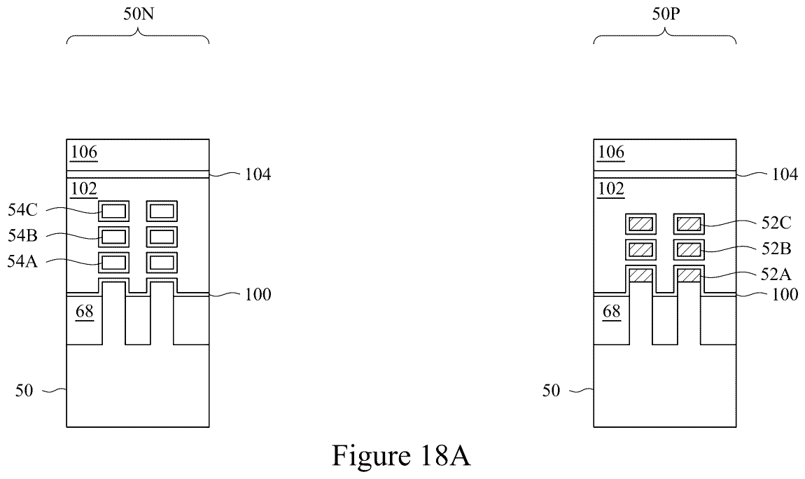

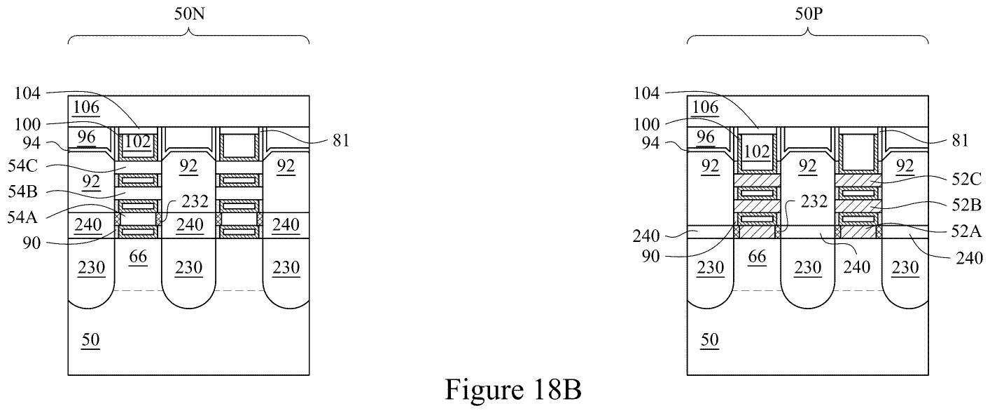

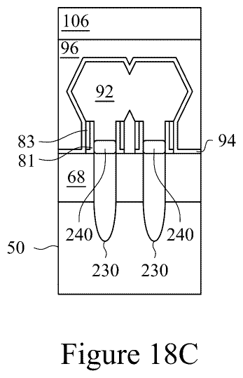

FIGS. 18A, 18B, and 18C show the gate structure (including the gate dielectric layers 100 and the corresponding overlying gate electrodes 102) that may be recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts penetrate through the gate mask 104 to contact the top surface of the recessed gate electrodes 102.

As further illustrated by FIGS. 18A, 18B, and 18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

FIGS. 19A, 19B, and 19C show the second ILD 106, the first ILD 96, the CESL 94, and the gate masks 104 may be etched to form recesses 108 exposing surfaces of the epitaxial source/drain regions 92 and/or the gate structure. The recesses 108 may be formed by etching using an anisotropic etching process, such as RIE, NBE, or the like. In some embodiments, the recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the recesses 108 extend into the epitaxial source/drain regions 92 and/or the gate structure, and a bottom of the recesses 108 may be level with (e.g., at a same level, or having a same distance from the substrate), or lower than (e.g., closer to the substrate) the epitaxial source/drain regions 92 and/or the gate structure. Although FIG. 19B illustrate the recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 includes TiSi, and has a thickness in a range between about 2 nm and about 10 nm. As shown in FIG. 19B, in the n-type region 50N, the nanostructures 52 may be removed and replaced with gate structures 195 that are wrapped around the nanostructures 54. In the p-type region 50P, the nanostructures 54 may be removed and replaced with gate structures 195 that are wrapped around the nanostructures 52. Each gate structure 195 includes a gate electrode 102 in contact with the gate dielectric layers 100. In each nano-FET, the gate structures 195, e.g., the gate electrodes 102 of the gate structures 195, are in contact with each other. In the p-type region 50P, the gate structure 195 is in contact with the nanostructures 52 such that the gate electrodes 102 is connected to the nanostructures 52 through the gate dielectric layers 100. In the n-type region 50N, the gate structure 195 is in contact with the nanostructures 54 such that the gate electrodes 102 is connected to the nanostructures 54 through the gate dielectric layers 100.

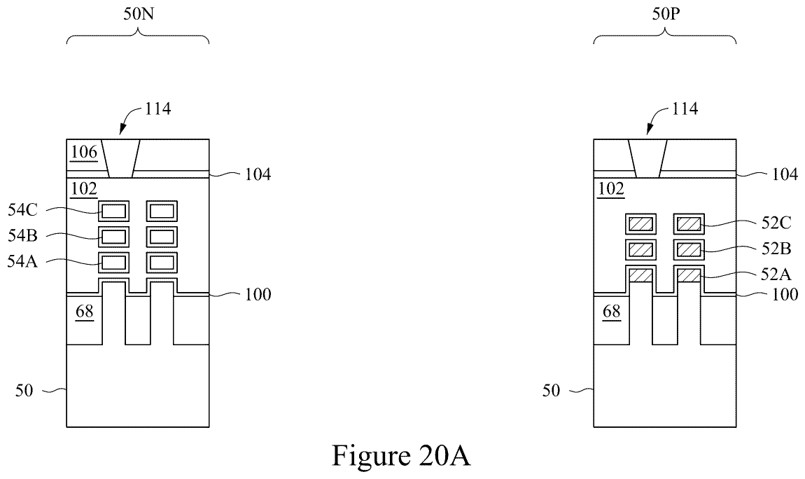

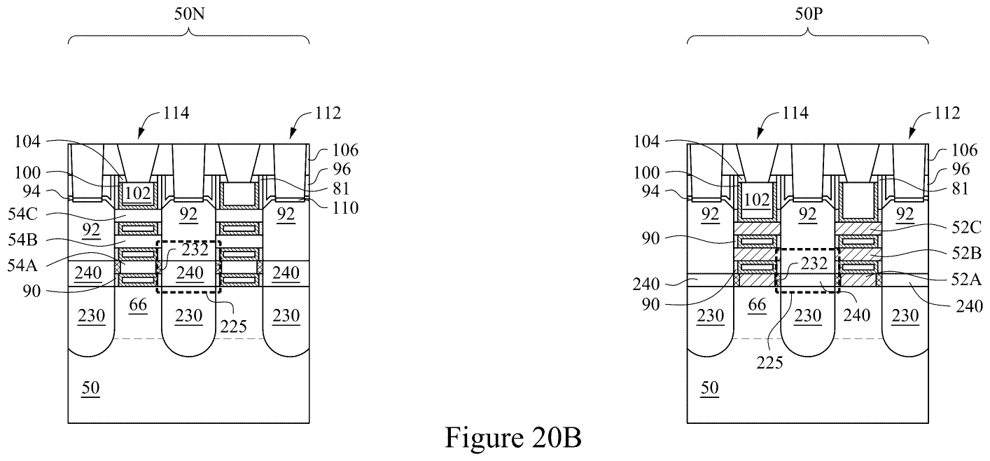

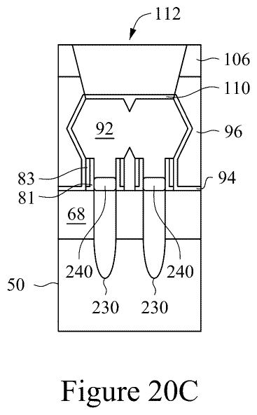

FIGS. 20A, 20B, and 20C show contacts 112 and 114 (may also be referred to as contact plugs) that may be formed in the recesses 108. The contacts 112 and 114 may each include one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrodes 102 and/or silicide region 110 in the illustrated embodiment). The contacts 114 are electrically coupled to the gate electrodes 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

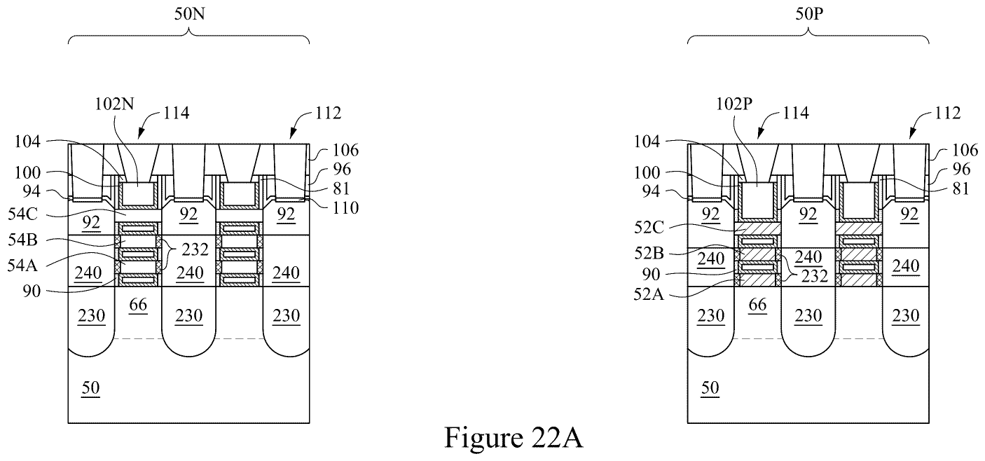

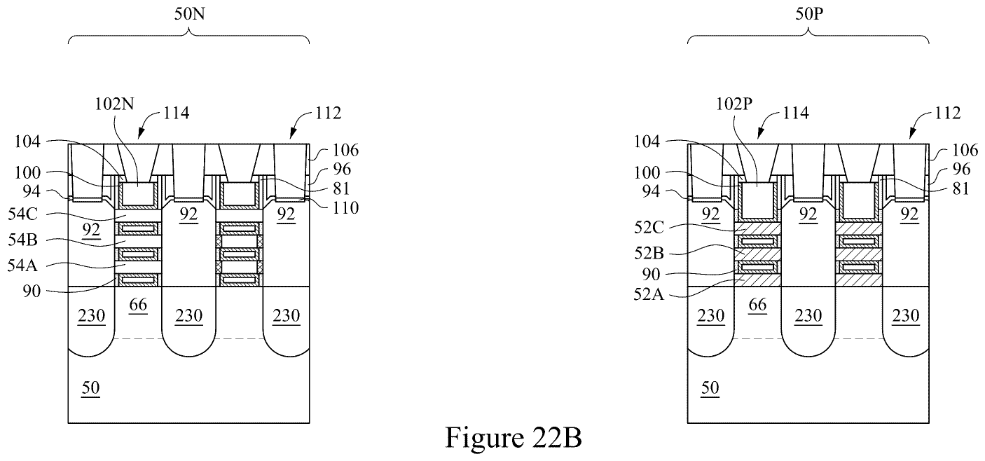

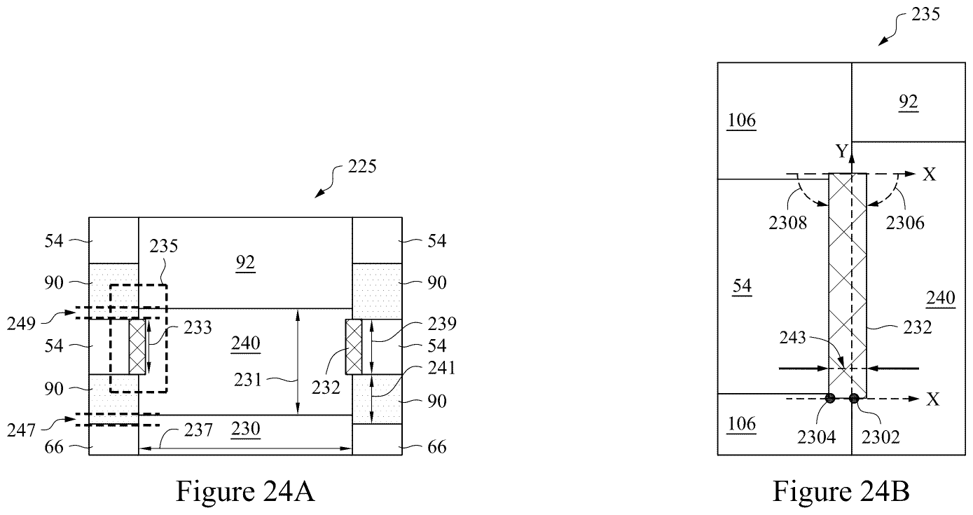

FIGS. 21A, 21B, and 21C are cross-sectional views of a nano-FET, in accordance with some embodiments of the disclosure. FIG. 21A illustrates reference cross-section A-A′ illustrated in FIG. 1. FIG. 21B illustrates reference cross-section B-B′ illustrated in FIG. 1. FIG. 21C illustrates reference cross-section C-C′ illustrated in FIG. 1. In FIGS. 21A, 21B, and 21C, like reference numerals indicate like elements formed by like processes as the structure of FIGS. 22A, 22B, and 22C. However, in FIGS. 21A-C, channel regions in the n-type region 50N and the p-type region 50P include a same material. For example, the second nanostructures 54, which include silicon, provide channel regions for p-type nano-FETs in the p-type region 50P and for n-type nano-FETs in the n-type region 50N. The structure of FIGS. 21A, 21B, and 21C may be formed, for example, by removing the first nanostructures 52 from both the p-type region 50P and the n-type region 50N simultaneously; depositing the gate dielectric layers 100 and the gate electrodes 102P (e.g., gate electrode suitable for a p-type nano-FET) around the second nanostructures 54 in the p-type region 50P; and depositing the gate dielectric layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above. FIG. 21B also shows a portion 225 of the source/drain trench 86. The portion 225 for different passivation layers is described with respect to the FIGS. 24A, 24B, 25A, 25B, 26A, 26B, 27A, and 27B.

FIGS. 22A and 22B are cross-sectional views of a nano-FET, in accordance with some embodiments of the disclosure. FIG. 22A is consistent with FIG. 20B with the difference that in FIG. 22A two channels are closed, e.g., blocked, and only one channel is open. FIG. 22B is consistent with FIG. 20B with the difference that in FIG. 22B, no channel is closed and all channels are open and conducting.

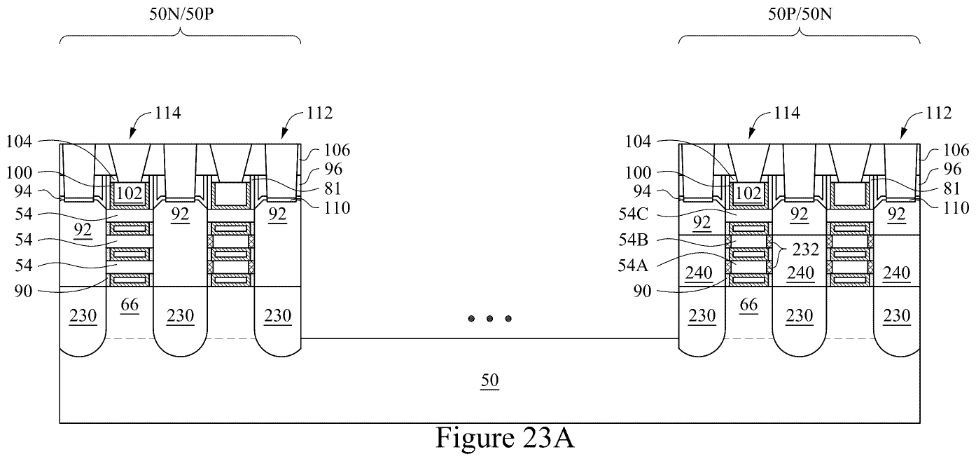

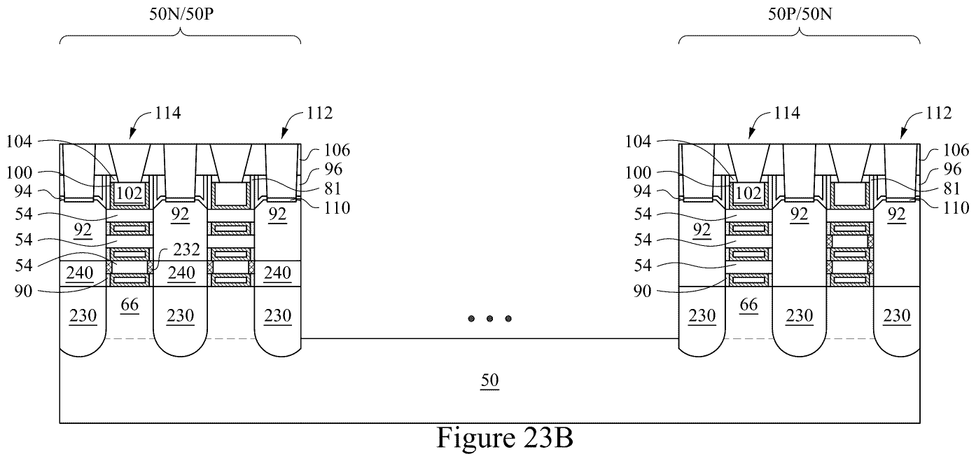

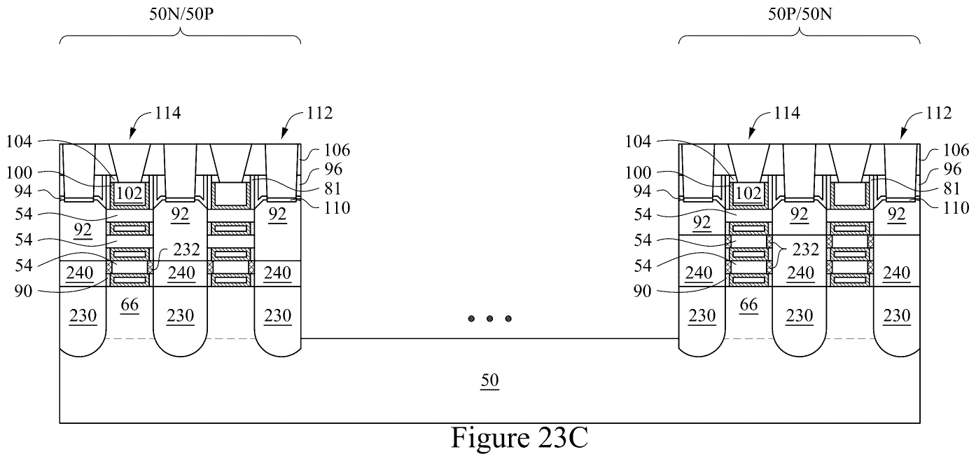

FIGS. 23A, 23B, and 23C illustrate cross-sectional views of an intermediate stage in the manufacturing of source/drain regions of two or more nano-FETs 222 (e.g., semiconductor devices) on a substrate, in accordance with some embodiments of the disclosure. FIGS. 23A, 23B, and 23C show two or more nano-FETs 222 on the substrate 50 that are located at different locations of a semiconductor circuit. FIG. 23A shows one nano-FET 222 that has more open channels than closed channels and another nano-FET 222 at another location has more closed channels than open channels. FIG. 23B shows one nano-FET 222 that has no closed channel and all channels are open and another nano-FET 222 at another location has one closed channel and two open channels. FIG. 23C shows one nano-FET 222 that has one closed channel and two channels that are open and another nano-FET 222 at another location has two closed channel and one open channel. Each nano-FET 222 is either in the n-type region 50N or in the p-type region 50P.

FIGS. 24A, 24B, 25A, 25B, 26A, 26B, 27A, and 27B illustrate cross-sectional views of passivation layers in the source/drain regions of nano-FETs, in accordance with some embodiments of the disclosure. FIG. 24A shows the portion 225 of FIG. 22E and shows the bottom portion 230, semiconductor layer 240, and the epitaxial source/drain region 92. FIGS. 24A and 24B also shows the passivation layers 232 having a rectangular shape with a height 233 that is between 3 nm and 20 nm and a thickness 243 that is between 0.2 nm and 5 nm. FIG. 24B shows a portion 235 of FIG. 24A. The bottom portion 230, the semiconductor layer 240, and epitaxial source/drain regions 92 have a same width 237 that is between 10 nm and 50 nm and the semiconductor layer 240 has a height 231 that is between 3 nm and 90 nm. Heights 239 and 241 of the nanostructures 54 and the inner spacers 90, which are the same as the heights of the nanostructures 54 are between 3 nm and 15 nm. A distance 249 between respective bottom of upper inner spacers 90 and bottom of the epitaxial source/drain regions 92 is between 5 nm and 10 nm. A distance 247 between respective bottom of the lower inner spacers 90 and bottom of the semiconductor layer 240 with respect to the bottom of the lower inner spacers 90 as a reference line is between 5 nm and −10 nm. An edge 2304 of the passivation layers 232 with respect to an edge 2302 of the semiconductor layer 240 (as the reference point) is between 5 nm and −10 nm (e.g., recessed by 10 nm). Also, the angles 2306 and 2308 between top surface of the passivation layer 232 with the faces of the passivation layers 232 are between 80 degrees and 110 degrees. Also, the height 239 of the nanostructures 54 is smaller than the height 233 of the passivation layer 232 such that the passivation layer 232 effectively covers the nanostructures 54.

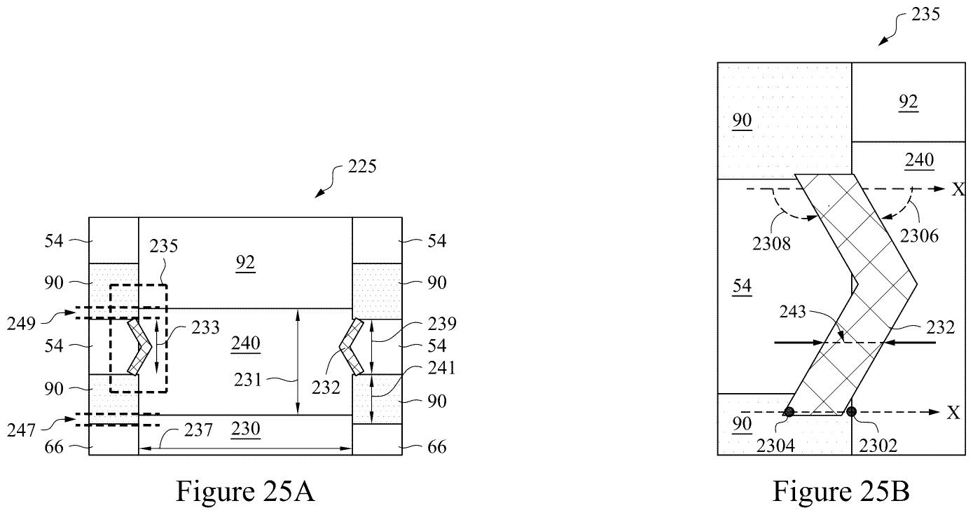

FIGS. 25A and 25B show same items as FIGS. 24A and 24B such that same item numbers are used for the same features and have the same values or value ranges and with the difference that the passivation layers 232 has a pointy shape pointing towards a center of the semiconductor layer 240. Also, the angle 2308 is between 130 degrees and 150 degrees and the angle 2306 is between 40 degrees and 60 degrees.

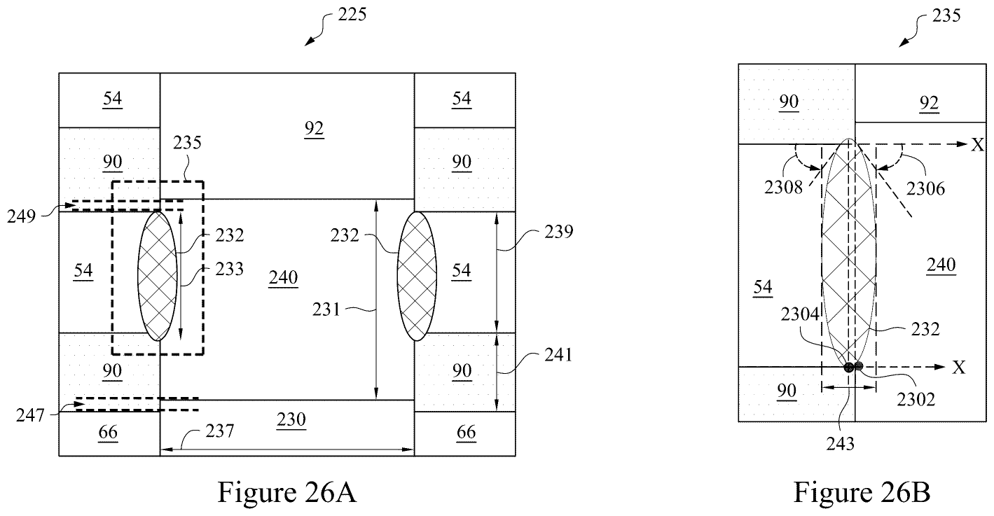

FIGS. 26A and 26B show same items as FIGS. 24A and 24B such that same item numbers are used for the same features and have the same values or value ranges and with the difference that the passivation layers 232 has a lens shape. Also, the angle 2308 is between 70 degrees and 90 degrees and the angle 2306 is between 70 degrees and 90 degrees. The angles 2306 and 2308 are calculated from a bottom surface of the epitaxial source/drain regions 92 to surfaces tangent to the lens shape as shown.

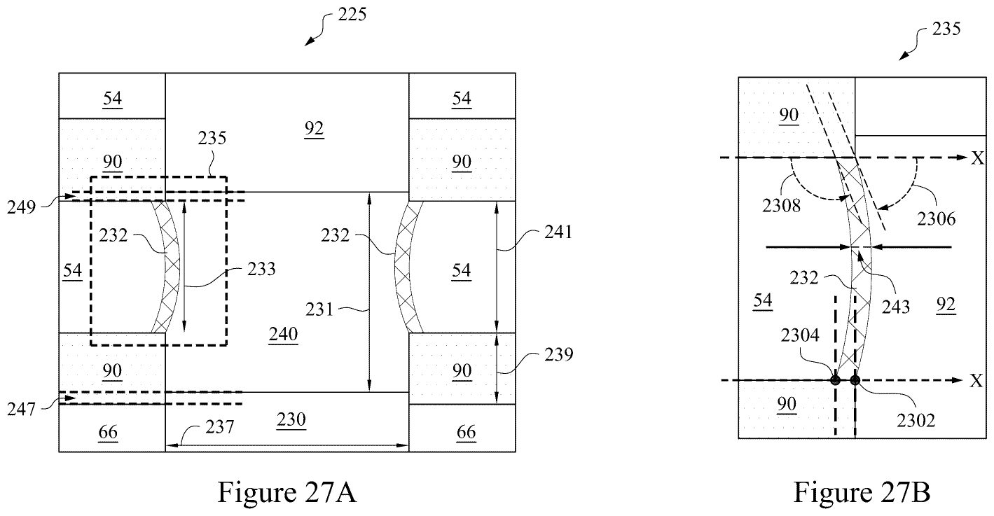

FIGS. 27A and 27B show same items as FIGS. 24A and 24B such that same item numbers are used for the same features and have the same values or value ranges and with the difference that the passivation layers 232 has a disk shape. Also, the angle 2308 is between 90 degrees and 130 degrees and the angle 2306 is between 50 degrees and 90 degrees. The angles 2306 and 2308 are calculated from a bottom surface of the epitaxial source/drain regions 92 to surfaces tangent to the lens shape as shown.

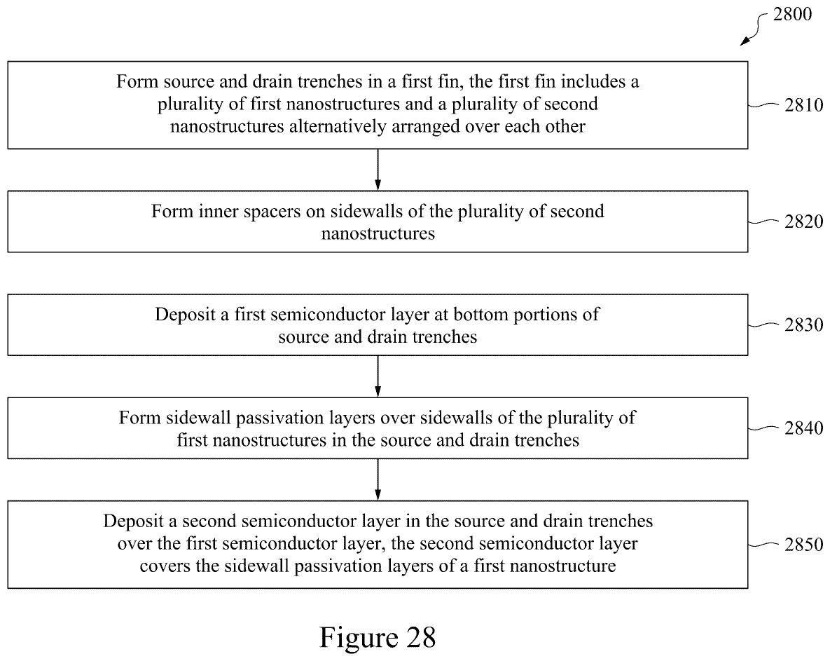

FIG. 28 illustrates a flow diagram of a process 2800 for manufacturing of nano-FETs, according to some embodiments of the disclosure of the disclosure. The steps of the process are shown in FIGS. 11A, 11B, 11C, 12A, 12B, 12C, 13A, 13B, 13C, 22A, 22B, 22C, 22D, and 22E. At step 2810, source and drain trenches are formed in a first fin. As shown in FIG. 13A, source and drain trenches 86 are formed in a semiconductor fin 66. In some embodiments, the first fin includes a plurality of first nanostructures 54 and a plurality of second nanostructures 52 alternately arranged over each other.

At step 2820, inner spacers are formed on sidewalls of the plurality of second nanostructures. As shown in FIG. 11C, inner spacers 90 may be formed on sidewalls of the plurality of the second nanostructures 52 in the n-type region 50N and the inner spacers 90 are not formed sidewalls of the plurality of the first nanostructures 54 in the n-type region 50N. As described above, in the n-type region, the second nanostructures 52 may be removed and replaced with gate structures 195 of a nano-FET. The first nanostructures 54 may perform as channels of the nano-FET and the gate structures 195 wrap around the channels.

At step 2830, a first semiconductor layer is deposited at bottom portions of source and drain trenches. As shown in FIG. 22A, a first semiconductor layer is deposited at the bottom portion 230 of the source and drain trenches 86.

At step 2840, sidewall passivation layers are formed over sidewalls of the plurality of first nanostructures in the source and drain trenches. As shown in FIG. 22B, passivation layers 232 are formed over sidewalls of the plurality of first nanostructures 54 in the source and drain trenches 86.

At step 2850, a second semiconductor layer is deposited in the source and drain trenches over the first semiconductor layer. As shown in FIG. 22C, a semiconductor layer 240 is deposited over the bottom portion 230. The semiconductor layer 240 covers one of the first nanostructures 54 and the passivation layers 232. The passivation layers 232 that are not covered are later removed.

As described in the embodiments above, a passivation layer may be produced between the source/drain region and the channel. The passivation layer may prevent current through one or more channels and, thus, reduce source-drain current of the nano-FET. The passivation layer may also prevent the migration of the elements between the channel and the source/drain region during deposition and etching and may prevent etching of the channel region and, thus, may preserve the critical dimension.

According to an embodiment, a method includes forming source and drain first trenches in a first fin, such that the first fin includes a plurality of first nanostructures and a plurality of second nanostructures that are alternately formed over each other. The method also includes forming inner spacers on sidewalls of the plurality of second nanostructures and depositing a first semiconductor layer at bottom portions of source and drain first trenches, such that the first semiconductor layer extends to a bottom-most nanostructure. The method also forming sidewall passivation layers over sidewalls of the plurality of first nanostructures in the source and drain first trenches and depositing a second semiconductor layer in the source and drain first trenches over the first semiconductor layer, such that the second semiconductor layer covers the sidewall passivation layers of a first nanostructure at sidewalls of the source and drain first trenches.

In an embodiment, a top passivation layer is formed over the first semiconductor layer, the method further includes: prior to depositing the second semiconductor layer, removing the top passivation layer from over the first semiconductor layer. In an embodiment, the first fin is formed over a semiconductor substrate, the method further includes: forming source and drain second trenches in a second fin that is formed over the semiconductor substrate, where the second fin includes a plurality of first nanostructures and a plurality of second nanostructures that are alternately formed over each other, depositing a third semiconductor layer at bottom portions of source and drain second trenches, where the third semiconductor layer extends to a bottom-most nanostructure, forming sidewall passivation layers over the sidewalls of the plurality of first nanostructures in the source and drain second trenches, and depositing a fourth semiconductor layer in the source and drain second trenches over the third semiconductor layer, the fourth semiconductor layer covers the sidewall passivation layers of zero or more first nanostructure at sidewalls of the source and drain second trenches. In an embodiment, the method further includes directing nitrogen plasma to the sidewalls of the plurality of first nanostructures in the source and drain trenches to form the sidewall passivation layers that include crystalline silicon nitride. The sidewall passivation layers have a rectangular shape that at least covers the sidewalls of the plurality of first nanostructures and has a thickness between 1 nm to 3 nm. In an embodiment, the method further includes removing sidewall passivation layers over sidewalls of a group of the plurality of first nanostructures that are not covered by the second semiconductor layer, and epitaxially growing source and drain regions over the second semiconductor layer, where the source and drain regions are electrically connected to the first nanostructures that are not covered by the second semiconductor layer. Also, the third semiconductor layer has an n-type dopant concentration of about 10¹⁵ cm⁻³, the second semiconductor layer has an n-type dopant concentration of about 10¹⁶ cm⁻³, and the source and drain regions have an n-type dopant concentration of about 10²⁰ cm⁻³. In an embodiment, the second semiconductor layer covers the sidewall passivation layers of one or more additional first nanostructures and epitaxially grown source and drain regions are in electrical contact with the first nanostructures that are not covered by the second semiconductor layer. In an embodiment, the second semiconductor layer covers the sidewall passivation layers of two or more first nanostructure at sidewalls of the source and drain trenches, and the source and drain regions are not electrically connected to the two or more first nanostructure that are covered by the second semiconductor layer.

According to an embodiment, a method includes forming a source/drain trench in a semiconductor fin, where the semiconductor fin includes a plurality of first nanostructures and a plurality of second nanostructures that are alternately formed over each other. The method also includes depositing a first SiGe layer at a bottom portion of source/drain trench, where the first SiGe layer extends to a bottom-most nanostructure and forming sidewall passivation layers over sidewalls of the plurality of first nanostructures in the source/drain trench. The method further includes depositing a second SiGe layer in the source/drain trench over the first SiGe layer, where the second SiGe layer covers the sidewall passivation layers of one or more first nanostructures at sidewalls of the source/drain trench.

In an embodiment, the semiconductor fin is formed over a semiconductor substrate, and the source/drain trench extends into the semiconductor substrate. In an embodiment, a top passivation layer is formed over the first SiGe layer, the method further include: prior to depositing the second SiGe layer, removing the top passivation layer from over the first SiGe layer. In an embodiment, prior to depositing the first SiGe layer, inner spacers are formed on sidewalls of the plurality of second nanostructures in the source/drain trench. In an embodiment, the method further includes directing one of nitrogen plasma, silicon plasma, carbon plasma, or oxygen plasma to the sidewalls of the plurality of first nanostructures in the source/drain trench to form the sidewall passivation layers. The passivation layer is formed at a temperature between 300 degrees centigrade and 700 degrees centigrade. In an embodiment, the sidewall passivation layers that cover the sidewalls of the plurality of first nanostructures are recessed by about 10 nm. In an embodiment, the first nanostructures are gate channels, the method further include epitaxially growing source and drain regions over the second SiGe layer in the source/drain trench, and replacing the second nanostructures with gate structures.

According to an embodiment, a semiconductor device includes a first semiconductor fin over a semiconductor substrate, where the first semiconductor fin includes a plurality of first nanostructures. The semiconductor device also includes a gate electrode surrounding each of the plurality of first nanostructures and source and drain regions in the first semiconductor fin, where each one of the source and drain regions include: a first semiconductor layer, where the first semiconductor layer covers at least one of the plurality of first nanostructures and sidewall passivation layers on sidewalls of the at least one of the plurality of first nanostructures. The sidewall passivation layers are between the first semiconductor layer and the at least one of the plurality of first nanostructures.

In an embodiment, each one of the source and drain regions further includes a mesa over the semiconductor substrate, where the first semiconductor fin is over the mesa and the mesa includes SiGe. In an embodiment, the plurality of first nanostructures include up to 6 first nanostructures, where up to 2 first nanostructures include the sidewall passivation layers and are covered by the first semiconductor layer. In an embodiment, the first nanostructures include a semiconductor gate channel. In an embodiment, the sidewall passivation layers include one or more of silicon nitride, silicon dioxide, amorphous silicon, or silicon carbide. In an embodiment, the plurality of first nanostructures of the first semiconductor fin are n-type semiconductor, the semiconductor device further includes: a second semiconductor fin that includes a plurality of second nanostructures that are p-type semiconductor, where no first nanostructures of the first semiconductor fin includes the sidewall passivation layers, and where at least one of the second nanostructures of the second semiconductor fin includes the sidewall passivation layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming source and drain first trenches in a first fin, wherein the first fin comprises a plurality of first nanostructures and a plurality of second nanostructures that are alternately formed over each other;
forming inner spacers on sidewalls of the plurality of second nanostructures;
depositing a first semiconductor layer at bottom portions of source and drain first trenches, wherein the first semiconductor layer extends to a bottom-most nanostructure;
forming sidewall passivation layers over sidewalls of the plurality of first nanostructures in the source and drain first trenches; and
depositing a second semiconductor layer in the source and drain first trenches over the first semiconductor layer, wherein the second semiconductor layer covers the sidewall passivation layers of a first nanostructure at sidewalls of the source and drain first trenches.

2. The method of claim 1, wherein a top passivation layer is formed over the first semiconductor layer, the method further comprising:
prior to depositing the second semiconductor layer, removing the top passivation layer from over the first semiconductor layer.

3. The method of claim 1, wherein the first fin is formed over a semiconductor substrate, the method further comprising:
forming source and drain second trenches in a second fin that is formed over the semiconductor substrate, wherein the second fin comprises a plurality of first nanostructures and a plurality of second nanostructures that are alternately formed over each other;
depositing a third semiconductor layer at bottom portions of source and drain second trenches, wherein the third semiconductor layer extends to a bottom-most nanostructure;
forming sidewall passivation layers over the sidewalls of the plurality of first nanostructures in the source and drain second trenches; and
depositing a fourth semiconductor layer in the source and drain second trenches over the third semiconductor layer, wherein the fourth semiconductor layer covers the sidewall passivation layers of zero or more first nanostructure at sidewalls of the source and drain second trenches.

4. The method of claim 3, further comprising:
removing sidewall passivation layers over sidewalls of a group of the plurality of first nanostructures that are not covered by the second semiconductor layer; and
epitaxially growing source and drain regions over the second semiconductor layer, wherein the source and drain regions are electrically connected to the first nanostructures not covered by the second semiconductor layer, wherein: the third semiconductor layer has an n-type dopant concentration of about 10¹⁵ cm⁻³, the second semiconductor layer has an n-type dopant concentration of about 10¹⁶ cm⁻³, and the source and drain regions have an n-type dopant concentration of about 10²⁰ cm⁻³.

5. The method of claim 1, further comprising:
directing nitrogen plasma to the sidewalls of the plurality of first nanostructures in the source and drain trenches to form the sidewall passivation layers that comprise crystalline silicon nitride, wherein the sidewall passivation layers have a rectangular shape that at least covers the sidewalls of the plurality of first nanostructures and has a thickness between 1 nm to 3 nm.

6. The method of claim 5, wherein the second semiconductor layer covers the sidewall passivation layers of one or more additional first nanostructures, and wherein epitaxially grown source and drain regions are in electrical contact with the first nanostructures that are not covered by the second semiconductor layer.

7. The method of claim 6, wherein the second semiconductor layer covers the sidewall passivation layers of two or more first nanostructure at sidewalls of the source and drain trenches, and wherein the source and drain regions are not electrically connected to the two or more first nanostructure that are covered by the second semiconductor layer.

8. A method, comprising:
forming a source/drain trench in a semiconductor fin, wherein the semiconductor fin comprises a plurality of first nanostructures and a plurality of second nanostructures that are alternately formed over each other;
depositing a first SiGe layer at a bottom portion of source/drain trench, wherein the first SiGe layer extends to a bottom-most nanostructure;
forming sidewall passivation layers over sidewalls of the plurality of first nanostructures in the source/drain trench; and
depositing a second SiGe layer in the source/drain trench over the first SiGe layer, wherein the second SiGe layer covers the sidewall passivation layers of one or more first nanostructures at sidewalls of the source/drain trench.

9. The method of claim 8, wherein the semiconductor fin is formed over a semiconductor substrate, and wherein the source/drain trench extends into the semiconductor substrate.

10. The method of claim 8, wherein a top passivation layer is formed over the first SiGe layer, the method further comprising:
prior to depositing the second SiGe layer, removing the top passivation layer from over the first SiGe layer.

11. The method of claim 8, wherein prior to depositing the first SiGe layer, inner spacers are formed on sidewalls of the plurality of second nanostructures in the source/drain trench.

12. The method of claim 8, further comprising:
directing one of nitrogen plasma, silicon plasma, carbon plasma, or oxygen plasma to the sidewalls of the plurality of first nanostructures in the source/drain trench to form the sidewall passivation layers, wherein the passivation layer is formed at a temperature between 300 degrees centigrade and 700 degrees centigrade.

13. The method of claim 8, wherein the sidewall passivation layers that cover the sidewalls of the plurality of first nanostructures are recessed by about 10 nm.

14. The method of claim 8, wherein the first nanostructures are gate channels, the method further comprises:
epitaxially growing source and drain regions over the second SiGe layer in the source/drain trench; and
replacing the second nanostructures with gate structures.

15. A semiconductor device, comprising:
a first semiconductor fin over a semiconductor substrate, wherein the first semiconductor fin comprises a plurality of first nanostructures;
a gate electrode surrounding each of the plurality of first nanostructures;
source and drain regions in the first semiconductor fin, wherein each one of the source and drain regions comprise:
a first semiconductor layer, wherein the first semiconductor layer covers at least one of the plurality of first nanostructures; and
sidewall passivation layers on sidewalls of the at least one of the plurality of first nanostructures, wherein the sidewall passivation layers are between the first semiconductor layer and the at least one of the plurality of first nanostructures.

16. The semiconductor device of claim 15, wherein each one of the source and drain regions further comprises:
a mesa over the semiconductor substrate, wherein the first semiconductor fin is over the mesa, wherein the mesa comprises SiGe.

17. The semiconductor device of claim 15, wherein the plurality of first nanostructures comprises up to 6 first nanostructures, and wherein up to 2 first nanostructures include the sidewall passivation layers and are covered by the first semiconductor layer.

18. The semiconductor device of claim 15, wherein the first nanostructures comprise a semiconductor gate channel.

19. The semiconductor device of claim 15, wherein the sidewall passivation layers comprise one or more of silicon nitride, silicon dioxide, amorphous silicon, or silicon carbide.

20. The semiconductor device of claim 15, wherein the plurality of first nanostructures of the first semiconductor fin are n-type semiconductor, the semiconductor device further comprises:
a second semiconductor fin comprising a plurality of second nanostructures that are p-type semiconductor, wherein no first nanostructures of the first semiconductor fin includes the sidewall passivation layers, and wherein at least one of the second nanostructures of the second semiconductor fin includes the sidewall passivation layers.
